(19) United States
(12) Patent Application Publication
(10) Pub. No.: US 2020/0066521 A1
(43) Pub. Date: Feb. 27, 2020

(54) COLORED SELF-ALIGNED SUBTRACTIVE PATTERNING

(71) Applicant: INTEL CORPORATION, Santa Clara, CA (US)

(72) Inventors: Kevin LIN, Beaverton, OR (US); Rami HOURANI, Portland, OR (US); Elliot N. TAN, Potland, OR (US); Manish CHANDHOK, Beaverton, OR (US); Anant H. JAHAGIRDAR, Hillsboro, OR (US); Robert L. BRISTOL, Portland, OR (US); Richard E. SCHENKER, Portland, OR (US); Aaron Douglas LILAK, Beaverton, OR (US)

(21) Appl. No.: 16/489,331

(22) PCT Filed: Mar. 31, 2017
(86) PCT No.: PCT/US17/25509

§ 371 Date: Aug. 27, 2019

(51) Int. Cl. H01L 21/033; H01L 27/088; H01L 21/8234; H01L 21/311; H01L 21/32; H01L 21/3115

(52) U.S. Cl. CPC H01L 21/0337; H01L 27/0886; H01L 21/823431; H01L 21/0332; H01L 21/31144; H01L 21/32; H01L 21/31155; H01L 21/823456

(57) ABSTRACT

A computing device including tight pitch features and a method of fabricating a computing device using colored spacer formation is disclosed. The computing device includes a memory and an integrated circuit coupled to the memory. The integrated circuit includes a first multitude of features above a substrate. The integrated circuit die includes a second multitude of features above the substrate. The first multitude of features and the second multitude of features are same features disposed in a first direction. The first multitude of features interleave with the second multitude of features. The first multitude of features has a first size and the second multitude of features has a second size.

### BACKGROUND

Integrated circuits (IC) have continued to shrink as performance and cost demands have pushed designers to design integrated circuits with an increasing number of devices per unit area. Semiconductor manufacturing processes are continually developed and employed to enable the manufacture of smaller and smaller features on an IC.

### BRIEF DESCRIPTION OF THE DRAWINGS

The present disclosure described herein is illustrated by way of example and not by way of limitation in the accompanying figures. For simplicity and clarity of illustration, features illustrated in the figures are not necessarily drawn to scale. For example, the dimensions of some features may be exaggerated relative to other features for clarity. Further, where considered appropriate, reference labels have been repeated among the figures to indicate corresponding or analogous elements.

FIG. 1 illustrates a fabrication process including first operations for forming features of an integrated circuit, according to implementations.

FIG. 2 illustrates a fabrication process including second operations for forming features of an integrated circuit, according to implementations.

FIG. 3 illustrates a fabrication process including third operations for forming features of an integrated circuit, according to implementations.

FIG. 4 illustrates a fabrication process including fourth operations for forming features of an integrated circuit, according to implementations.

FIG. 5 illustrates a fabrication process including fifth operations for forming features of an integrated circuit, according to implementations.

FIG. 6 illustrates a fabrication process including sixth operations for forming features of an integrated circuit, according to implementations.

FIG. 7 illustrates a fabrication process including seventh operations for forming features of an integrated circuit, according to implementations.

FIG. 8 illustrates a fabrication process including eighth operations for forming features of an integrated circuit, according to implementations.

FIG. 9 illustrates a fabrication process including ninth operations for forming features of an integrated circuit, according to implementations.

FIG. 10 illustrates a fabrication process including tenth operations for forming features of an integrated circuit, according to implementations.

FIG. 11 illustrates a fabrication process including eleventh operations for forming features of an integrated circuit, according to implementations.

FIG. 12 illustrates a fabrication process including twelfth operations for forming features of an integrated circuit, according to implementations.

FIG. 13 is a diagram illustrating features of an integrated circuit die using a fabrication process described with respect to FIGS. 1-12, according to implementations.

FIG. 14A illustrates an angled passivation process to adjust etch properties associated with some spacers, according to an implementation.

FIG. 14B illustrates a selective removal of some spacers based on the angled passivation process, according to an implementation.

FIG. 15A illustrates an angled passivation process to adjust etch properties associated with some spacers, according to an implementation.

FIG. 15B illustrates a selective growth process, according to an implementation.

FIG. 15C illustrates a selective removal of some spacers based on the angled passivation process and selective growth process, according to an implementation.

FIG. 16A illustrates an angled deposition process to adjust etch properties associated with some spacers, according to an implementation.

FIG. 16B illustrates a selective removal of some spacers based on the angled deposition process, according to an implementation.

FIG. 17A illustrates a resist process, according to an implementation.

FIG. 17B illustrates exposure of the resist to off-axis illumination to adjust etch properties associated with some spacers, according to an implementation.

FIG. 17C illustrates a selective removal of some spacers based on the off-axis illumination, according to an implementation.

FIG. 17D illustrates off-axis illumination, according to an implementation.

FIG. 18A illustrates an angled ion implantation process to adjust etch properties associated with some spacers, according to an implementation.

FIG. 18B illustrates a selective removal of some spacers based on the angled ion implantation process, according to an implementation.

FIG. 19A illustrates a flow diagram of a fabrication process for forming features of an integrated circuit, according to an implementation.

FIG. 19B illustrates a flow diagram of a fabrication process for forming features of an integrated circuit, according to an implementation.

FIG. 20 illustrates an interposer, according to implementations.

FIG. 21 is a computing device built in accordance with implementation of the present disclosure.

### DETAILED DESCRIPTION

In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Subtractive patterning may refer to a fabrication technique where a desired pattern (or feature) is defined by a layer, such as a resist layer, that protects the underlying materials from subsequent processes, such as etch. After etching is complete, the defining layer may be removed leaving the desired pattern or feature. A feature may be an element or physical structure of an integrated circuit, such as fin, gate, via, plug, etc., where the feature size of the element or physical structure is controllable within a tolerance. Feature size may be a physical measurement (e.g., width, length, etc.) of a feature. For electrical performance reasons, the critical dimensions of some features may be defined by spacer-based patterning techniques. For example, fabrication techniques, such as complementary patterning, may be used to create a predominantly one-dimensional pattern of spacers. Unwanted spacers may be cut or plugged to form the desired circuit pattern. As features get closer together, process variations (e.g., patterning size variation or overlay variation) may make cut or plug patterning prone to erroneously cutting the wrong spacers or miss cutting the desired spacers.

Aspects of the present disclosure addresses the above-mentioned and other deficiencies by “coloring” spacers so that every other spacer is a different material (or is associated with different etch properties). In implementations, spacer-based patterning may provide high controllability to help control features sizes for a semiconductor fabrication process. By having every other spacer (e.g., even and odd spacers) be a different material than adjacent spacers, a mask, such as a cut mask, may selectively etch spacers of a particular material per pass, allowing the cut mask to overlap a neighboring spacer of a different material without cutting the neighboring spacer. The disclosure allows for significantly more margin for edge placement errors of a mask and allows for a denser pattern of spacers to be used in a fabrication process. A denser pattern of spacers may allow for manufacture of an integrated circuit having features with tighter pitch. Pitch may refer to the sum of the feature size of a feature and the distance between the feature and another adjacent feature.

In implementations, aspects of the present disclosure adjust the etch properties associated with a first population of spacers selective to a second population of spacers. By changing the etch properties associated with a first population of spacers, either the first population of spacers or a second population of spacers may be removed selective to the other population. In some implementations, “coloring” of spacers may be performed by forming additional spacers in the areas created by the removal of the population of spacers. The additional spacers may be a different material or be associated with different etch properties than the population of spacers that were not removed.

In implementations, a first hardmask layer is formed above a substrate. In implementations, multiple backbone structures are formed above the first hardmask layer. In implementations, a first multitude of spacers of a first material are formed adjacent to first sides and second sides of the multiple backbone structures. The etch properties associated with the first multitude of spacers adjacent the second sides are adjusted. First spacers (or second spacers) of the first multitude of spacers that are adjacent to the first sides of the multitude of backbone structures are etched selective to the spacers on the opposite side of the backbone structures.

In implementations, a second multitude of spacers of a second material adjacent to the first sides and the second sides of the multiple backbone structures are formed. The third spacers of the second multitude of spacers that are adjacent to the second sides of the multiple backbone structures are asymmetrically etched. The multiple backbone structures protect fourth spacers of the second multitude of spacers that are adjacent to the first sides of the multiple backbone structures from being removed.

In implementations, the multiple backbone structures are selectively removed to leave the second spacers of the first material and the fourth spacers of the second material. In implementations, a second hardmask layer is formed above the second spacers of the first material and the fourth spacers of the second material. A trench in the second hardmask layer is etched to expose a first one of the second spacers and a first one of the fourth spacers. The first one of the second spacers is selectively etched respective the first one of the fourth spacers.

In implementations, another trench in the second hardmask layer is etched to expose a second one of the second spacers and a second one of the fourth spacers. The second one of the fourth spacers is selectively etched respective the second one of the second spacers. In implementations, the second hardmask layer is removed to expose remaining second spacers and remaining fourth spacers. The features of the integrated circuit are formed by transferring an etch pattern using the remaining second spacers and remaining fourth spacers. In implementations, the features the integrated circuit include fins of transistors. In implementations, the features the integrated circuit include gates of transistors.

In implementations, the first material of the first multitude of spacers is a different material than the second material of the second multitude of spacers. In implementations, the first material of the first multitude of spacers and the second material of the second multitude of spacers have different etch properties.

In implementations, an integrated circuit die, wafer, or computing device includes a substrate and a first multitude of features above the substrate. The integrated circuit die, wafer, or computing device includes a second multitude of features above the substrate. The first multitude of features and the second multitude of features are same features disposed in a first direction. The first multitude of features interleave with the second multitude of features. The first multitude of features has a first size and the second multitude of features has a second size.

In implementations, each of the first multitude of features are disposed between a different two of the second multitude of features. In implementations, the first multitude features and the second multitude of features are gates of transistors. In implementations, the first multitude features and the second multitude of features are fins of transistors.

In implementations, the first size and the second size are a width in the first direction. In implementations, the first size is an average width of the first multitude of features, and the second size is an average width of the second multitude of features where the first size is different from the second size. In implementations, the first multitude of features and the second multitude of features are a local subset of features of the integrated circuit die or computing device.

In implementations, adjusting the etch properties associated with the first multitude of spacers on the second sides includes performing angled passivation of the second spacers of the first multitude of spacers that are adjacent to the second sides include performing angled passivation of the second spacers of the first multitude of spacers that are adjacent to the second sides of the multitude of backbone structures selective to the first spacers of the first multitude of spacers that are adjacent to the first sides of the multitude of backbone structures. In implementations, etching selectively one of the first spacers or the second spacers includes etching the first spacers selective to the second spacers based on the passivated second spacers having different etch properties than the first spacers.

In implementations, adjusting the etch properties associated with the first multitude of spacers adjacent the second sides includes performing angled passivation of the second spacers of the first multitude of spacers that are adjacent to the second sides of the multitude of backbone structures selective to the first spacers of the first multitude of spacers that are adjacent to the first sides of the multitude of backbone structures. The method also includes growing a layer above the first spacers selective to the second spacers. The passivated second spacers prevent growth of the layer above the second spacers. The second spacers are etched selective to the first spacers based on the passivated second spacers having different etch properties than the layer above the first spacers.

In implementations, adjusting the etch properties associated with the first multitude of spacers adjacent the second sides includes performing angled deposition of a layer above the second spacers that are adjacent to the second sides of the multitude of backbone structures selective to the first spacers that are adjacent to the first sides of the multitude of backbone structures. The first spacers are etched selective to the second spacers based on the layer above the second spacers having different etch properties than the first spacers.

In implementations, adjusting the etch properties associated with the first multitude of spacers adjacent the second sides includes depositing a resist layer above the first spacers and the second spacers. The method also includes exposing the resist layer to off-axis illumination that exposes the resist layer in a first area adjacent the first spacers and prevents exposure of the resist layer in a second area adjacent the second spacers. In implementations, the method also includes etching the first spacers selective to the second spacers. The resist layer in the first area adjacent the first spacers is removed and the resist layer in the second area remains to prevent etch of the second spacers.

In implementations, adjusting the etch properties associated with the first multitude of spacers adjacent the second sides includes performing ion implantation on the second spacers that are adjacent to the second sides of the multitude of backbone structures selective to the first spacers that are adjacent to the first sides of the multitude of backbone. The ion implantation changes the etch properties of the second spacers. The one of the first spacers or second spacers is selectively etched based on the changed etch properties of the second spacers.

It may be noted that for purposes of illustration, rather than limitation, that aspects of the present disclosure describe processes and features for fabricating fins and gates above a substrate of an integrated circuit. It may be noted that aspects of the present disclosure may be applied to features, components, layers, etc. of an IC other than described herein. For example, processes described herein may be applied to form transistor features (e.g., gate, source, drain, fin, channel, etc.) of a transistor (e.g., bipolar junction transistors (BJT), field effect transistors (FET), such as metal-oxide-semiconductor FET, Fin FET, multiple-gate FET (MuFET) etc.). In other examples, the processes described herein may form features of diodes, light-emitting diodes (LED), or memory cells, among others. In still other examples, the processes described herein may be used on the various layers of an IC or interconnects and vias between layers.

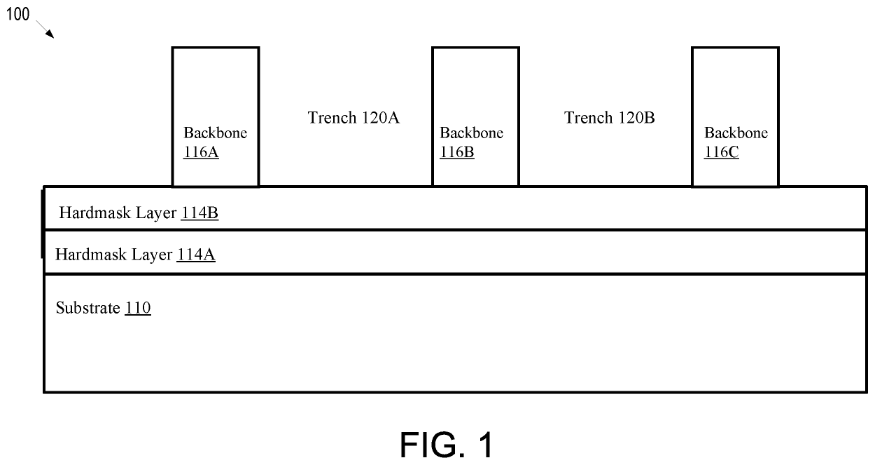

FIGS. 1-12 illustrate a fabrication process using adjacent spacers associated with different materials or etch properties to form features of an integrated circuit or computing device, according to implementations. Fabrication processes 100 through 1200 include an integrated circuit die of a wafer at various stages of the fabrication process, according to one implementation. It may be noted that fabrication processes 100-1200 are shown for purposes of illustration, rather than limitation. Fabrication processes 100-1200 may be performed in any order, include any number of processes, and include additional, the same, or fewer processes. It may also be noted that for purposes of illustration, rather than limitation, materials are described for the various layers or structures illustrated in fabrication processes 100-1200. Other materials, other than or in addition to the materials described with respect to FIGS. 1-12, may also be used in other implementations. It may be noted that for purposes of illustration, rather than limitation, the integrated circuit die may be diced from a wafer or be part of a wafer. It may also be noted that a layer (e.g., hardmask layer 114A, hardmask layer 114B, hardmask layer 714A, hardmask layer 714B, etc.), described herein, may include one or more layers. In implementations, each layer may include the same or different materials as other layers. It may be noted that the number of elements (e.g., backbone structures 116, spacers 220, spacers 430, etc.) are shown for purposes of illustrations, rather than limitation. In implementations, the elements described herein may be any number and depend on for example, the design of the integrated circuit.

In FIG. 1, process 100 shows hardmask layer 114A above substrate 110, and hardmask layer 114B above hardmask layer 114A. Backbone structures 116A-116C are formed above hardmask layer 114B. In implementations, the substrate 110 may be a variety of materials, including, but not limited to, Silicon, Gallium Nitride (GaN), Germanium, Sapphire, or Silicon Carbide such as 3C-Silicon Carbide (3C-SiC). In implementations, the substrate 110 may be silicon on insulator (SOI). In implementations, the crystallographic orientation of a substantially monocrystalline substrate may be any of (100), (111), or (110). Other crystallographic orientations are also possible. In implementations, the crystallographic orientations of the substrate 110 may be offcut. In one implementation, the substrate 110 is (100) silicon with crystalline substrate surface region having cubic crystallinity. In another implementation, for a (100) silicon substrate, the semiconductor surface may be miscut, or offcut, for example 2-10° toward [110]. In another implementation, substrate 110 is (111) silicon with crystalline substrate surface region having hexagonal crystallinity.

It may be noted that elements herein may be described using a number and letter. Elements that are described with a number and letter may be collectively described using a number without a letter. For example, backbone structure(s) 116 may refer to backbone structure 116A and/or backbone structure 116B, and/or backbone structure 116C, while reference to backbone structure 116A may refer to only backbone structure 116A, unless otherwise specified.

Hardmask layer 114A (also referred to as a “hard mask” or “protective layer” herein) may be formed, deposited, or grown above substrate 110. Hardmask layer 114B may be formed, deposited, or grown above hardmask layer 114A, In one exemplary implementation, a hardmask layer, such as hardmask layers 114, may be Silicon Nitride (Si₃N₄). A hard mask layer, such as hardmask layer 114, may be a variety of materials including one or more of Silicon Oxide (SiO₂) or Silicon Nitride (Si₃N₄). In one implementation, hardmask layer 114B is a different material than hardmask layer 114A.

In one implementation, hardmask layer 114 is a dielectric material. Representative dielectric materials may include, but are not limited to, various Oxides, Nitrides and Carbides, for example, Silicon Oxide, Titanium Oxide, Hafnium Oxide, Aluminum Oxide, Oxynitride, Zirconium Oxide, Hafnium Silicate, Lanthanum Oxide, Silicon Nitride, Boron Nitride, Amorphous Carbon, Silicon Carbide, Amorphous Silicon, or other similar dielectric materials. In one implementation, hardmask layer 114A is deposited, for example, by a plasma deposition process, to a thickness to serve as a mask to substrate 110 (e.g., to protect from undesired modification of the underlying layer from energy used in a subsequent process, such as subsequent mask registration). In one embodiment, a representative thickness of hardmask layer 114 is on the order of 30 angstroms (A) ±20 A. In another embodiment, a representative thickness of hardmask layer 114 is on the order of two to five nanometers (nm). In some implementations, the thickness of hardmask layer 114 may be 5 nm to 15 nm. In other implementations, hardmask layer 114 may be any other thickness.

Process 100 illustrates the formation of backbone structures 116 above hardmask layer 114B. Backbone may also be referred to as “backbone structure” or “mandrel” or “mandrel structure,” herein. In implementations, a backbone material may be deposited or grown above the hardmask layer 114B as a conformal layer. Backbone materials include, but are not limited to, Polysilicon, Amorphous Silicon, Amorphous Carbon, Silicon Nitride and Germanium. Backbone structures 116 may offer structural support or scaffolding to create one or more spacers of different material, as described below. In an implementation, backbone structures 116 may be a different material and have different etch properties from the spacers described below.

In implementations, a layer of backbone material may be deposited above hardmask layer 114B. A photoresist material may be patterned to define one or more trenches (e.g., trenches 120) within the layer of backbone material. The photoresist material may form a pattern over the layer of backbone material that may in turn, be used to form a pattern within the backbone material for the opening of trenches 120 to form backbone structures 116A -116B, as illustrated in FIG. 1. In implementations, the backbone structures 116 may be formed using lithography (e.g., 193 nanometer (nm) or extreme ultraviolet lithography (EUV)). Removal of remaining resist or an anti-reflection layer may be performed using ash or wet cleans, for example.

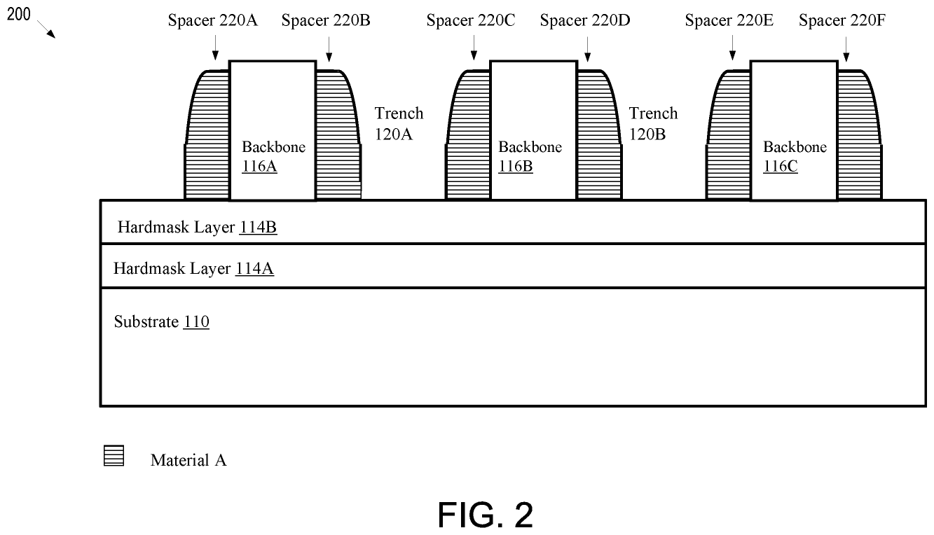

In FIG. 2, process 200 shows the formation of spacers 220 (e.g., spacers 220A-F) on the sides of backbone structures 116, according to implementations. In implementations, spacers 220 are formed using the same spacer material, illustrated as material A. The spacer material may be any material. In one implementation, the spacer material may be a dielectric material. Examples of dielectric materials are described at least with respect to hardmask layer 114, above. In other implementations, the spacer material may be a metal, or oxide or nitride of a metal. For example, Titanium Oxide or Titanium Nitride may be used as a spacer material. In other implementations, the spacer material may be Zirconium Oxide (ZrN), Zirconium Nitride (ZrN), Hafnium Oxide (HfO), Hafnium Nitride (HfN), or Aluminum Oxide (AlOₓ).

In some implementations, the spacers 220 may be formed by atomic layer deposition (ALD). ALD may be used to control the deposition of materials at the atomic level by depositing a single layer of atoms at a time. ALD may deposit spacers 220 with a feature size in the range of 1 nm to 10 nm with a tolerance of less than or equal to 2 nm. It may be noted that spacers wider than 10 nm may be formed using ALD or other processing technique.

In implementations, subsequent to depositing the spacer material for spacers 220, the hardmask layer 114B may be etched (e.g., anisotropic etch) to remove any superfluous spacer material from hardmask layer 114B, such as in the area of trenches 120 so as to prepare hardmask layer 114B for subsequent processes. It may be noted that other or additional techniques may be implemented to form spacers, such as spacers 220. In one implementation, spacers 220 may be formed using selective growth techniques or directed self-assembly (DSA), for example. In still other implementations, lithography techniques may be used to form larger spacers (e.g., greater than 50 nm).

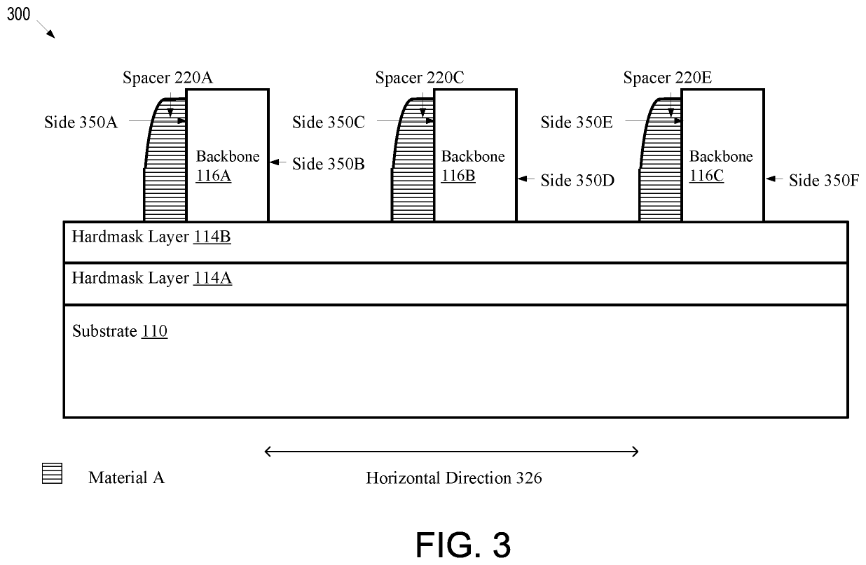

In FIG. 3, process 300 shows the removal of spacers selective to adjacent spacers. For example, spacers 220B, 220D, and 220E positioned on the respective right sides (e.g., side 350B, 350D, and 350F) of backbone structures 116 are shown to be removed selective to spacers 220A, 220C, and 220E positioned on the respective left sides (e.g., side 350A, 350C, and 350E) of backbone structures 116. It may also be noted that the etch properties of spacers one side of the backbone structures 116 (e.g., left side or right) may be adjusted (not shown) to facilitate the selective removal of one population of spacers selective another population of spacers.

For the sake of illustration, rather than limitation, spacers may be referred to as odd spacers or even spacers. Odd spacers (e.g., spacers 220A, 220C, and 220E) may refer to the spacers on one side of the backbone structures 116, such as the left side of the backbone structures 116, and even spacers (e.g., spacers 220B, 220D, and 220E) may refer to spacers on the opposite side of backbone structures 116, such as the right side of backbone structures 116. It may be noted that for purposes of illustration, rather than limitation, even spacers have been removed selective to odd spacers. In other implementations, odd spacers may be removed selective to even spacers. It may be noted that the subsequent processes may be suitably adjusted and employed to address odd spacers being removed, rather than the even spacers as illustrated. In a variety of implementations, different processes may be used to remove one population of spacers (e.g., even spacers) selective to another population of spacers (e.g., odd spacers).

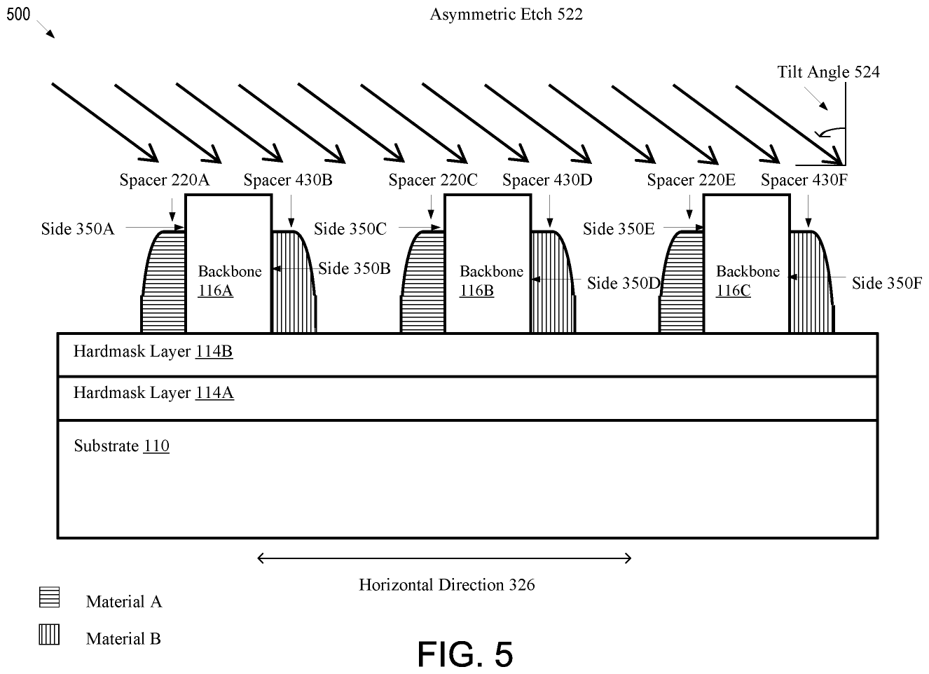

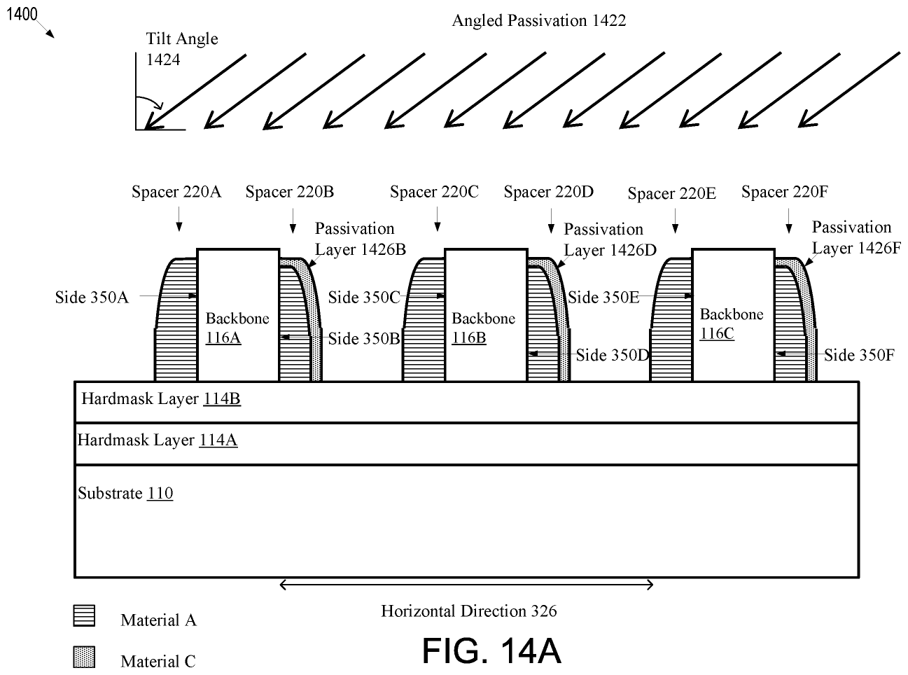

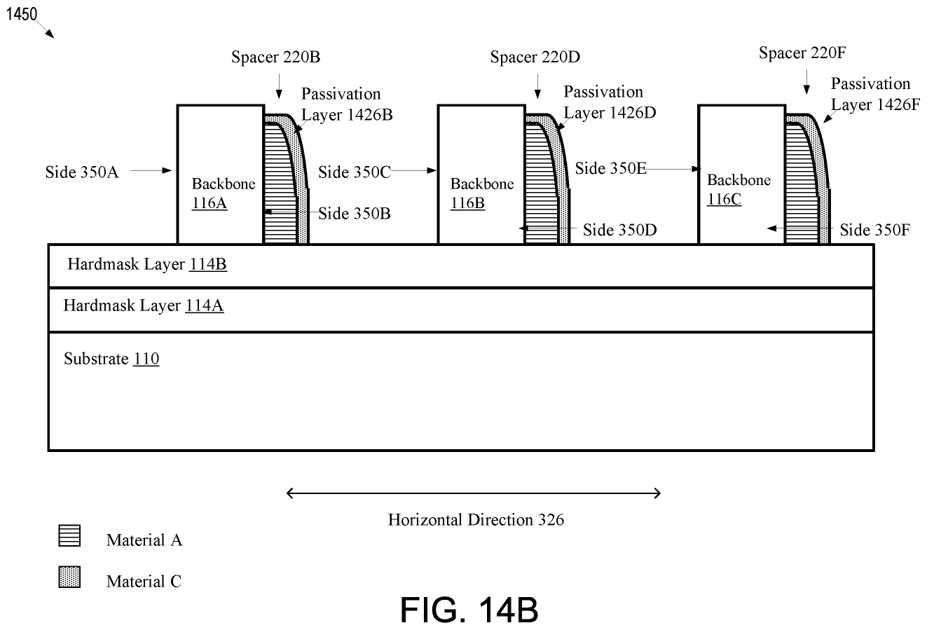

It may be noted that different processes to adjust the etch properties associated with one population of spacers and to remove a population of spacers selective another population of spacers are further described at least with respect to FIGS. 14A-18. It may be further noted, that in addition to the processes described with respect to FIGS. 14A-18, the removal of a population of spacers selective another population of spacers may be performed by asymmetric etch as described with respect to FIG. 5.

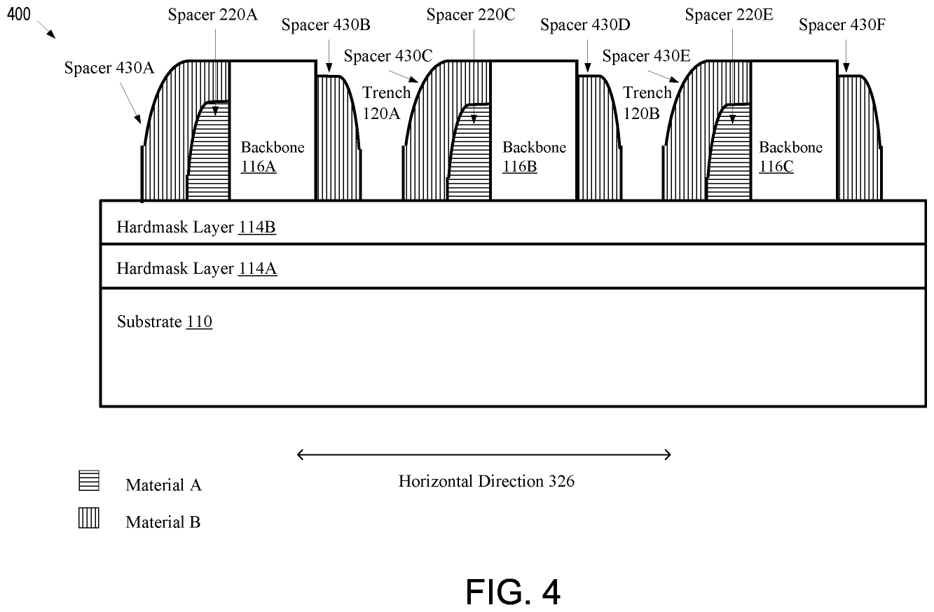

In FIG. 4, process 400 illustrates the deposition of spacers 430 of another spacer material, spacer material B. In implementations, spacer material of spacers 430 (e.g., material B) may be spacer material that is different than the spacer material used for spacers 220 (e.g., material A). Spacer material of spacers 430 may have different etch properties than the spacer material of spacers 220. In implementations, backbone structures 116 may use a different material than spacers 430 and spacers 220. The spacer material of spacers 430 may be one or more of the materials described with respect to spacers 220 in with FIG. 2.

In implementations, the different spacer materials (e.g., spacer material A and spacer material B) may have different etch properties. Etch properties may refer to a property (e.g., etch rate) or response of a material to a particular etch process. In one example, different etch properties may refer to the etch rate of the target material (e.g., material A) compared to the etch rate of other materials (e.g., material B or others) exposed to an etch process having a high ratio (e.g., high etch selectivity). In some implementations, etch selectivity may be from 3 to 1 rates, to 1000 to 1 rates. In implementations, spacers with different etch properties may be exposed to an etch process to remove a spacer with one etch property without removing spacers having different etch properties (at least not enough to materially affect the remaining spacers).

In implementations, using spacers of different materials with different etch properties allows for the selective removal of a particular spacer without removing neighboring spacers with different etch properties. In implementations having features with tight pitch (e.g., 40 nm or below), the additional margin for error granted by the use of spacers of different materials allows for the manufacture of an IC with smaller features sizes and greater reliability.

In implementations, spacers 430 may be formed in a similar manner as described with respect to spacers 220 of FIG. 2. In implementations, spacers 430 are all formed using the same spacer material illustrated as spacer material B. In some implementations, the spacers 430 may be formed by atomic layer deposition (ALD). ALD may deposit spacers 430 with a feature size in the range of 1 nm to 10 nm with a tolerance of less than or equal to 2 nm. It may be noted that spacers wider than 10 nm may be formed using ALD or other processing technique. Subsequent to depositing the spacer material for spacers 430, the hardmask layer 114B lay be etched (e.g., anisotropic etch) to remove any superfluous spacer material of spacers 430 from hardmask layer 114B, such as in the area of trench 120, to prepare hardmask layer 114B for subsequent processes. It may be appreciated that other or additional techniques may be implemented to form spacers, such as spacers 430. In one implementation, spacers 430 may be formed using selective growth techniques or directed self-assembly (DSA), for example.

In an implementation, one or more of spacers 430 may have a feature size in the range of 3 nm to 15 nm with a tolerance of less than or equal to 2 nm. In implementations, all the spacers 430 may have the same features size (e.g. width) within a tolerance (e.g., 1 nm) and all the spacers 220 may have the same features size within a tolerance, where the features size of spacers 430 and spacers 220 are different. In implementations, the average width of spacers 220 may differ from the average width of spacers 430. In some examples, the average width of spacers 220 may differ from the average width of spacers 430 by 2 or more Angstroms. In some examples, the average width of spacers 220 may differ from the average width of spacers 430 in a range of 2 to 10 Angstroms. In implementations, difference in average width of spacers 220 may occur within a local area or across the entire, integrated circuit die, computing device, or wafer.

In FIG. 5, process 500 illustrates an asymmetric angled etch 522 (also referred to as “asymmetric etch” herein) to remove spacers 430A, 430C and 430E positioned on the respective left sides (e.g., side 350A, 350C, and 350E) of backbone structures 116. In one implementation, the asymmetric angled etch 522 removes one-half of the spacers 430 (e.g., odd spacers 430). In implementations, the backbone structures 116 protect spacers 430B, 430D, and 430F, which are on the opposite sides (e.g., side 350B, 350D, and 350F) of backbone structures 116, from being removed. It may be noted that the protected spacers 430B, 430D, and 430F are opposite a source of an ion beam, for example, in the horizontal direction 326. In implementations, the tilt angle 524 of the asymmetric etch 522 may be in a range from 15 degrees to 40 degrees from vertical. It may be noted that the chosen tilt angle 524 may be defined by the aspect ratio of desired features and may include parameters such as feature size, pitch, depth, etc. Tilt angle may refer to the angle between the source or source beam (illustrated by angled arrows) and a plane or line normal (e.g., horizontal direction 326) to the wafer surface (e.g., substrate 110). In some implementations, tilt angle 524 is the angle between the ion beam (illustrated by angled arrows) and a plane or line normal to the wafer surface (e.g., substrate 110). As noted above, the remaining spacers 430B, 430D, and 430F are of a same spacer material, illustrated by spacer material B. It may also be noted that spacers 220A, 220C, and 220E may be exposed to asymmetric etch 522, but may have a different spacer material (e.g., spacer material A) with different etch properties than spacer material B of spacers 430. Asymmetric etch 522 may have a limited or non-material effect on exposed spacers 220A, 220C, and 220E. In implementations, etch chemistry and spacer material may be co-optimized

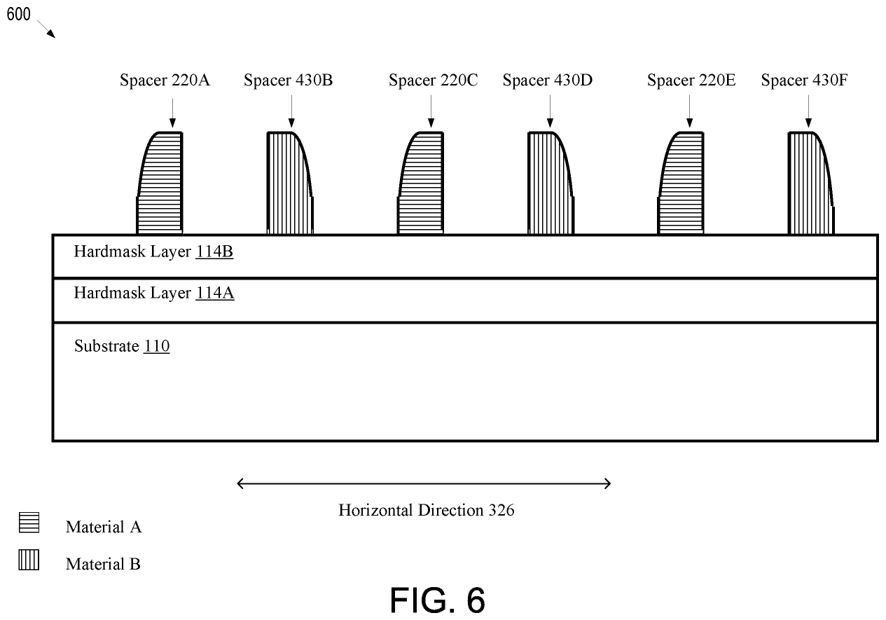

In FIG. 6, process 600 illustrates the removal of backbone structures 116, according to an implementation. In an implementation, backbone structures 116 may be selectively etched leaving spacers 220A, 220C, 220E, 430B, 430D, and 430F. In another implementation, backbone structures 116 may not be removed. For example, backbone structures 116 may be used to form some additional features in subsequent processes. In an implementation, backbone structures 116 uses a backbone material with different etch properties than remaining spacers 220 and 430.

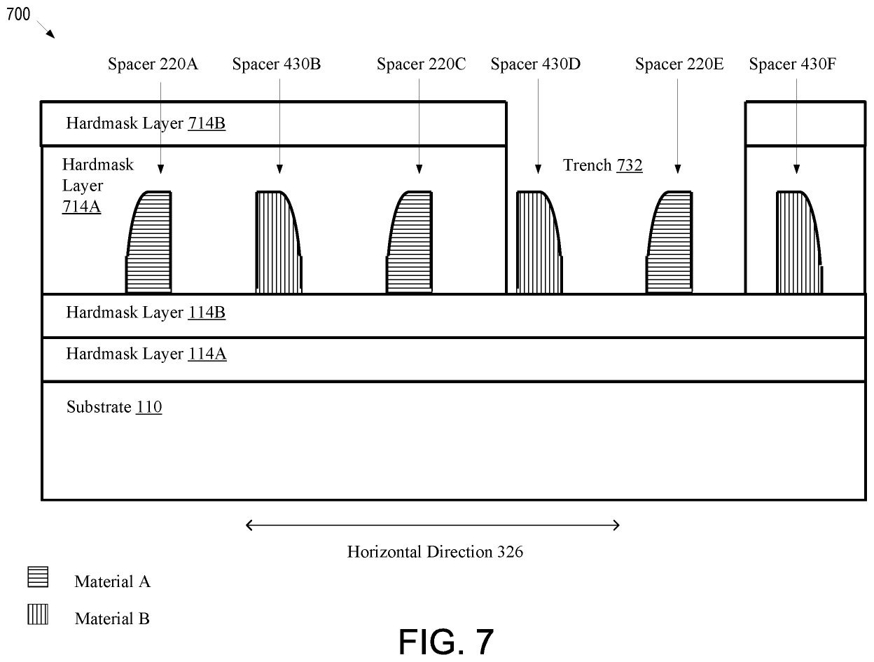

In FIG. 7, process 700 illustrates a cut process to expose at least one spacer. It may be noted that the cut process may have some process variation, and rather than expose a single spacer, expose two or more spacers, such as spacer 430D and spacer 220E in trench 732. Since spacer 430D and spacer 220E are of different spacer materials (e.g., spacer material B and spacer material A, respectively) with different etch properties, greater edge placement margin may be achieved at least because a particular spacer may be selectively removed without removing an adjacent spacer of a different spacer material.

In implementations, hardmask layer 714A is formed, deposited, or grown above hardmask layer 114B and cover at least spacers 220 and 430. Hardmask layer 714B is formed, deposited, or grown above hardmask layer 714A. Hardmask layer 714A and 714B may be formed in a similar manner or be a similar material as described with respect to hardmask layer 114 of FIG. 1. In one implementation, hardmask layer 714A may be carbon-based hardmask layer, and hardmask layer 714B may be an antireflective coating (ARC) layer, such as a Silicon ARC (SiARC) layer. A mask, such as a cut mask, may be used to open trench 732 to expose spacer 430D and 220E.

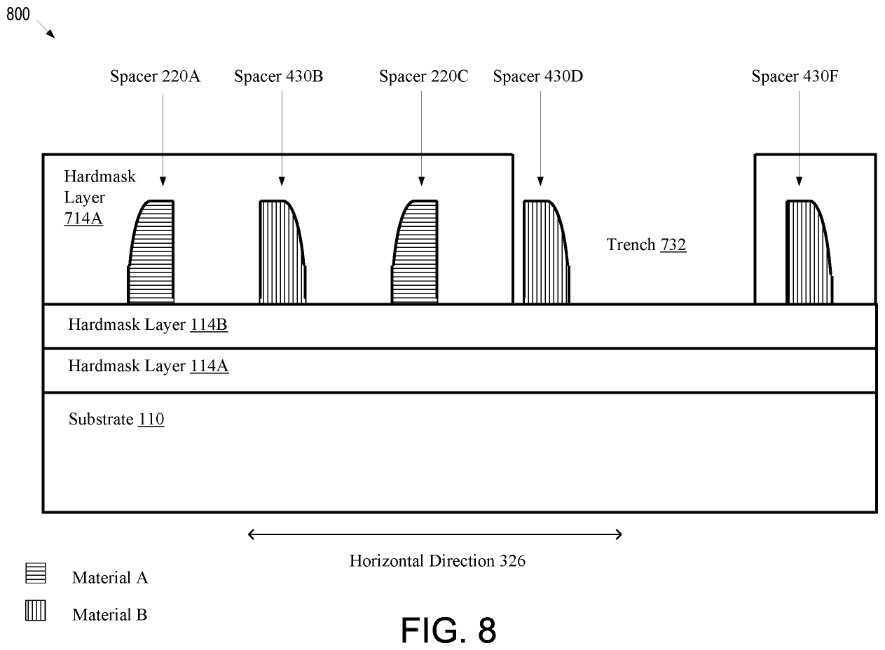

In FIG. 8, process 800 illustrates the selective etch of spacer 220E of spacer material (type) A. As described above, spacer 220E may be selectively etched at least because of the differences in etch properties of spacer materials A and B. In implementations, spacer 220E of spacer material A may be removed without removing spacer 430D of the spacer material B, both of which are exposed to the same etch process. In implementations, hardmask layer 714B may also be removed during the same etch process or at a different time using a different removal process.

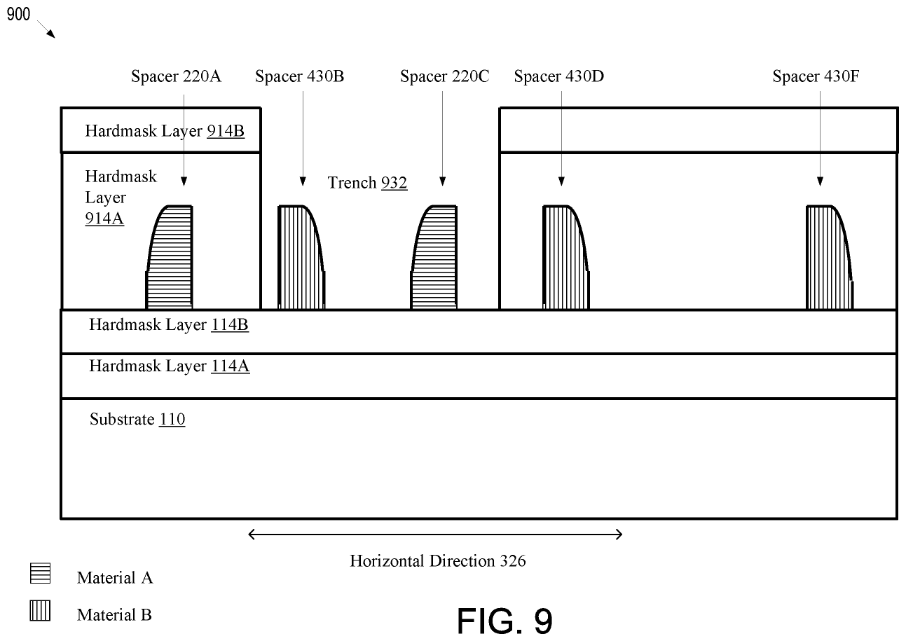

In FIG. 9, process 900 illustrates a cut process to expose at least one spacer, and is similar to process 700 of FIG. 7. It may be noted that the cut process may have some process variation in edge placement, and rather than expose a single spacer, exposes two or more spacers, such as spacer 430B and spacer 220C in trench 932.

In implementations, hardmask layer 914A is formed, deposited, or grown above hardmask layer 114B and cover at least spacers 220 and 430. In implementations, hardmask layer 914A may be the same layer as hardmask layer 714A, but with trench 732 filled, and the hardmask layer 714 re-planarized, for example. Hardmask layer 914B is formed, deposited, or grown above hardmask layer 914A. Hardmask layer 914A and 914B may be formed in a similar manner or be a similar material as described with respect to hardmask layer 114 of FIG. 1. In one implementation, hardmask layer 914A may be carbon-based hardmask layer, and hardmask layer 914B may be an antireflective coating (ARC) layer, such as a Silicon ARC (SiARC) layer. A mask, such as a cut mask, may be used to open trench 932 to expose spacer 430B and 220C.

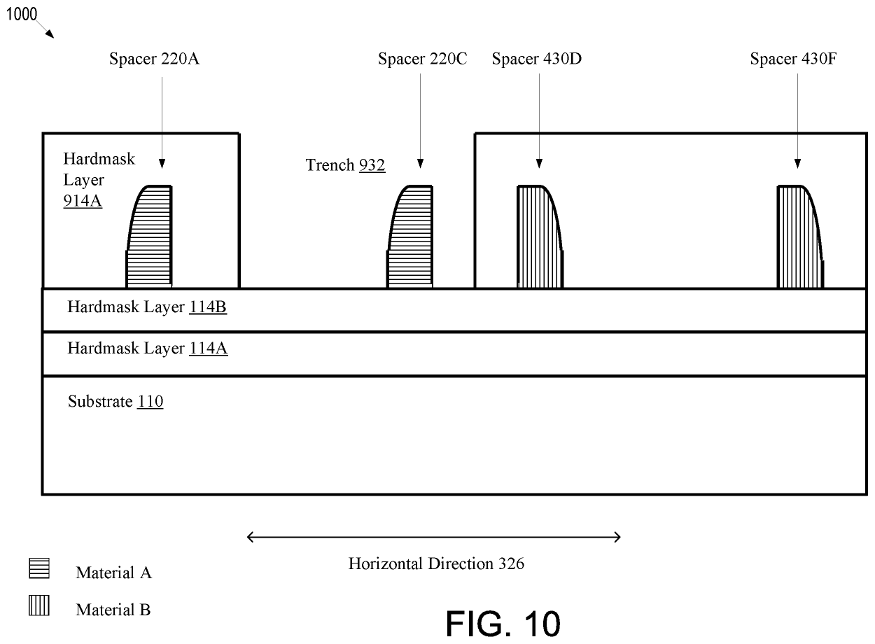

In FIG. 10, process 1000 illustrates the selective etch of spacer 430B of spacer material (type) B. In implementations, spacer 430B may be selectively etched at least because of the differences in etch properties of spacer materials A and B. In implementations, spacer 430B of spacer material B may be removed without removing spacer 220C of the spacer material A, both of which are exposed to the same etch process. Since spacer 430B and spacer 220C are of different spacer materials (e.g., spacer material B and spacer material A, respectively) with different etch properties, greater edge placement margin may be achieved at least because a particular spacer may be selectively removed without removing an adjacent spacer of a different spacer material. In implementations, hardmask layer 914B may also be removed during the same etch process or removed at a different time using a different removal process.

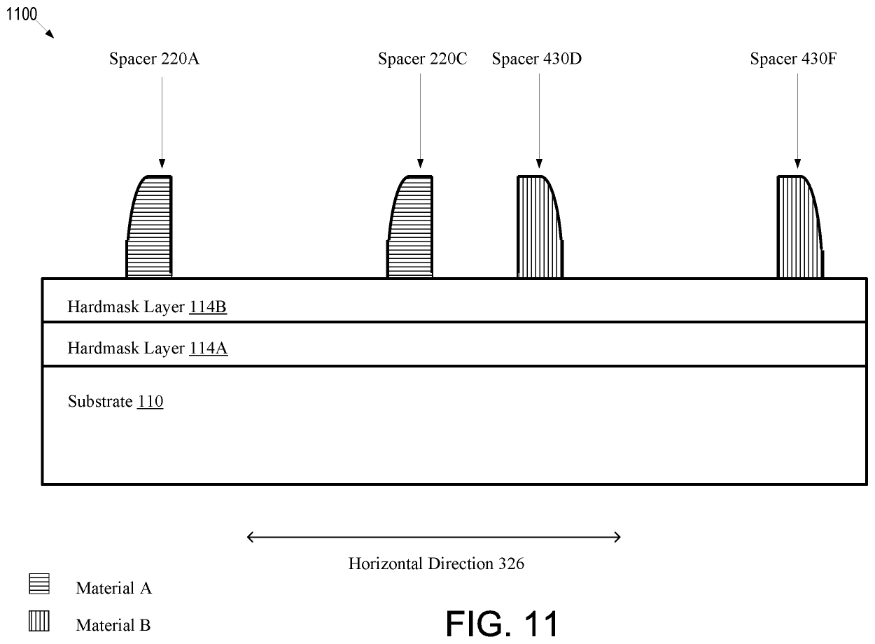

In FIG. 11, process 1100 illustrates the removal of hardmask layer 914A to expose the remaining spacers 220A, 220C, 430D, and 430F. In implementations, the exposure of the remaining spacers 220A, 220C, 430D, and 430F is in preparation to transfer the spacer pattern to the underlying materials (e.g., subtractive patterning) to form features in the desired final materials.

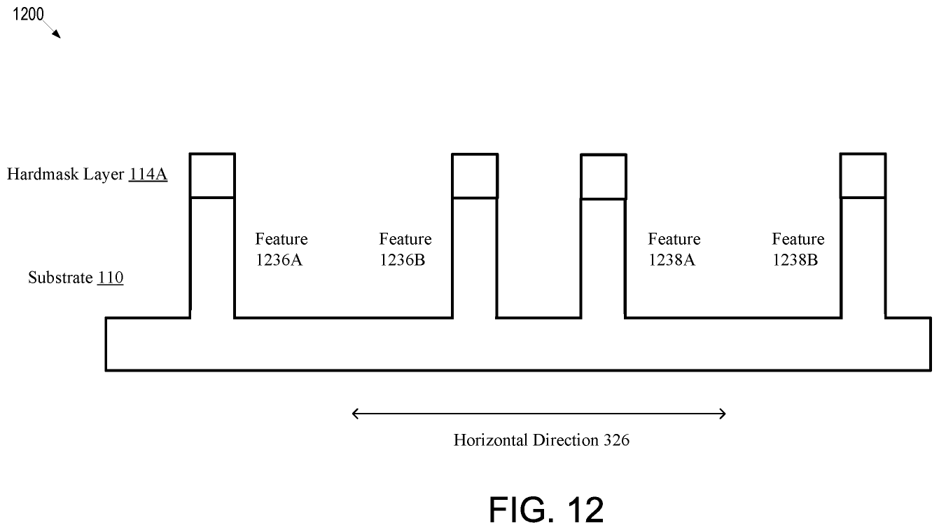

In FIG. 12, process 1200 illustrates the transfer of the spacer pattern created by spacers 220A, 220C, 430D, and 430F to the underlying materials, hardmask layer 114A and substrate 110. Spacers 220A, 220C, 430D, and 430F may act like mask to protect the underlying materials from subtractive processes, such as etch. It may be noted that the underlying materials may be any materials. In other implementations, the removed underlying materials may be above substrate 110 and not include substrate 110. In implementations, the patterning process may form features, such as features 1236, of an integrated circuit. In implementations, features 1236 may be fins or gates of transistors. Features 1236 may be any feature of an integrated circuit or of an active component (e.g., transistor, LED, etc.) or of a passive component.

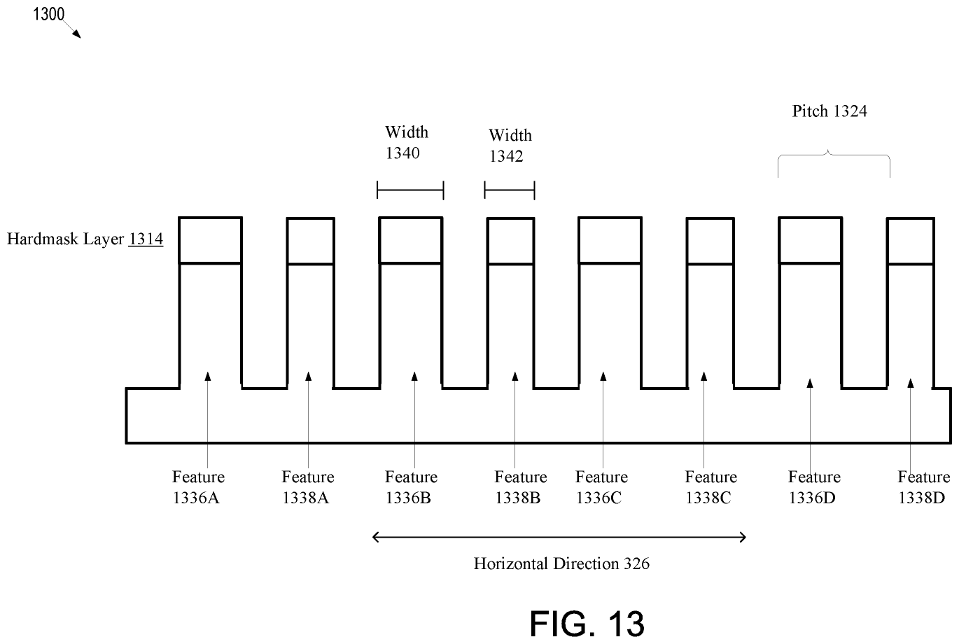

FIG. 13 is a diagram illustrating features of an integrated circuit die using a fabrication process described with respect to FIGS. 1-12 (and FIGS. 14A-18), according to implementations. In implementations, integrated circuit die 1300 may be formed using some or all the processes 100-1200 described with respect to FIGS. 1-12 (and some or all the processes described with respect to FIGS. 14A-18),. Integrated circuit die 1300 shows features 1336A-D and features 1338A-D. In implementations, features 1336A-D and features 1338A-D may be patterned from spacers of different materials or associated with different etch properties. For example, features 1336A-D may be patterned from spacers of spacer material A, and features 1338A-D may be patterned from spacers of spacer material B. In implementations, features 1336A-D and features 1338A-D may be the same features, such as all fins or all gates of transistors. Hardmask layer 1314 may be removed in a subsequent process to expose features 1336 and 1338. In some implementations, integrated circuit die 1300 may be an integrated circuit implemented on a larger integrated circuit die.

In implementations, spacers of one material (e.g., material A) may be a different width than spacers of a different material (e.g., material A). The variation in width may be attributable to at least the difference in the materials, the difference in processes, or the number of processes each spacer of a particular material undergoes. In implementations, the variation in width in the different spacer materials may affect the width of the underlying materials or features patterned from the spacers. As illustrated by integrated circuit die 1300, features 1336 made from spacers of material A may have a width 1340, and features 1338 made from spacers of material B may have a different width 1342 in the horizontal direction 326. In implementations, the average width of multiple features (e.g., group A) made from spacers of one material (e.g., features 1336 made from spacers of material A) may be different than the average width of multiple features (e.g., group B) made from spacers of a different material (e.g., features 1338 made from spacers of material B). In some implementations, the average width of the different groups of features (e.g., group A and B) may differ in width by 2 Angstroms or greater. In other implementations, the average width of the different groups of features (e.g., group A and B) may differ in the range of 2 to 10 Angstroms. Width may refer to a lateral width or size in the horizontal direction 326. In implementations, the difference in average width of features may occur within local regions (1-25 mm) or across the entire integrated circuit die, computing device, or wafer. For example, a local subset of the features of an integrated circuit die may have a difference in average width, but other regions may not have features with a difference in average width. In implementations, local or local regions may refer to a physical area (e.g., bounded physical area, such as a row or square) of an integrated circuit die, computing device, or wafer.

In implementations, the features of group A (e.g., features 1336) may interleave with features of group B (e.g., features 1338). For example, some features of group A (e.g., two or more) may be interspersed between two features of group B (not shown), in a repeating or non-repeating pattern. In other implementations, each feature of group A (e.g., features 1336 B-D, odd features) may be disposed between two different features of group B (e.g., features 1338, even features), so that the features of group A alternate with the features of group B. It may be noted that feature 1336A lies at on the end of integrated circuit die 1300 and may not be part of the group A in some implementations. In implementations, features of group A and group B may be a subgroup of features on an integrated circuit. For example, a SOC integrated circuit may have a logic circuit with features (e.g., fins) that is processed using processes 100-1200 described herein, and a memory circuit with features (e.g., fins) that are processed using different processing techniques.

In implementations, processes 100-1200 may be used to form features with tight pitch. Pitch 1324 illustrates example of a tight pitch, in accordance with implementations. In some implementations, the pitch 1324 may be in the range of 8 nm to 30 nm with a tolerance of ±2 nm. Tolerance herein may refer to plus or minus (±) a given value, unless otherwise described.

FIGS. 14A-B illustrate processes for the adjustment of etch properties associated with a first population of spacers and the removal of a second population of spacers selective the first population of spacers using selective angled passivation and etch, in accordance with implementations. Process 1400 shows angled passivation 1422 of the population of even spacers (e.g., spacers 220B, 220D, and 220F) selective to the population of odd spacers (e.g., spacers 220A, 220C, and 220E). A passivation layer (e.g., passivation layer 1426B, 1426D, and 1426F) may be formed in or on the respective spacers (e.g., spacers 220B, 220D, and 220F). Angled passivation 1422 may be performed at a tilt angle 1424 that uses elements, such as backbone structures 116 to shield one population of spacers (e.g., odd spacers) from the passivation material and prevent passivation of one population of spacers and that passivates another population of spacers (e.g., even spacers). Tilt angle may refer to the angle between the source or source beam (illustrated by angled arrows) and a plane or line normal (e.g., horizontal direction 326) to the wafer surface (e.g., substrate 110). In implementations, tilt angle 1424 may be in a range of 15 degrees to 40 degrees from vertical. It may be noted that the chosen tilt angle 1424 may be defined by the aspect ratio of desired features and may include parameters such as feature size, pitch, depth, etc. In implementations, the passivating material, such as material C, penetrates the spacers 220B, 220D, and 220F to a controllable depth so that the outer surface of the spacers (e.g., even spacers) is passivated and the bulk of the spacers is not passivated. In implementations, passivating the spacers (e.g., spacers 220B, 220D, and 220F) may change the etch properties associated with the passivated spacers (e.g., spacers 220B, 220D, and 220F) so that un-passivated (e.g., spacers 220A, 220C, and 220E) may be etched selective to the passivated spacers.

In implementations, angled passivation may be a process that encapsulates or penetrates a material to protect the underlying material or element from the environment or subsequent processes, for example. In implementations, angled passivation may be performed as a plasma process, such as fluorinating plasma process. For example, a plasma process may use plasmas to form a coating of fluorine-containing groups on the surface (or penetrate below the surface) of a population of spacers (e.g., spacers 220B, 220D, and 220F). The plasma may be deposited using an angular plasma exposure that allows passivation material to be applied to a desired depth in the selected population of spacers. In one implementation, the plasma may be made with Fluorine rich gases such as Carbon Tetrafluoride (CF₄), Difluoromethane (CF₂H₂), or a mixture of both gases. In another implementation, the CF₄ or CF₂H₂ may be mixed with other gases such as CH4, Silane, or other similar gases. It may be noted that other material or processes may be implemented to passivate a population of spacers selective to another population of spacers.

It may be noted that in some implementations some processes may be implemented while others are not implemented. For example in some implementations, subsequent to changing the etch properties associated with a population of spacers (e.g., even spacers) using angled passivation 1422, etch described with respect to FIG. 14B and spacer formation described with respect to FIGS. 4 and 5 may not be performed. In some implementations, changing the etch properties of a population of spacers (e.g., even spacers) using angled passivation 1422 may be followed by the removal of backbone structures 116 as described with respect to FIG. 6.

In FIG. 14B, process 1450 shows the removal of the un-passivated spacers (e.g., spacers 220A, 220C, and 220E) selective to the passivated spacers (e.g., spacers 220B, 220D, and 220F), in accordance with implementations. In implementations, the difference in etch properties between the passivated spacers and un-passivated spacers allows for an etch process to be performed that removes the un-passivated spacers without materially affecting the passivated spacers. In implementations, wet or dry etch may be performed to remove the un-passivated spacers selective to the passivated spacers.

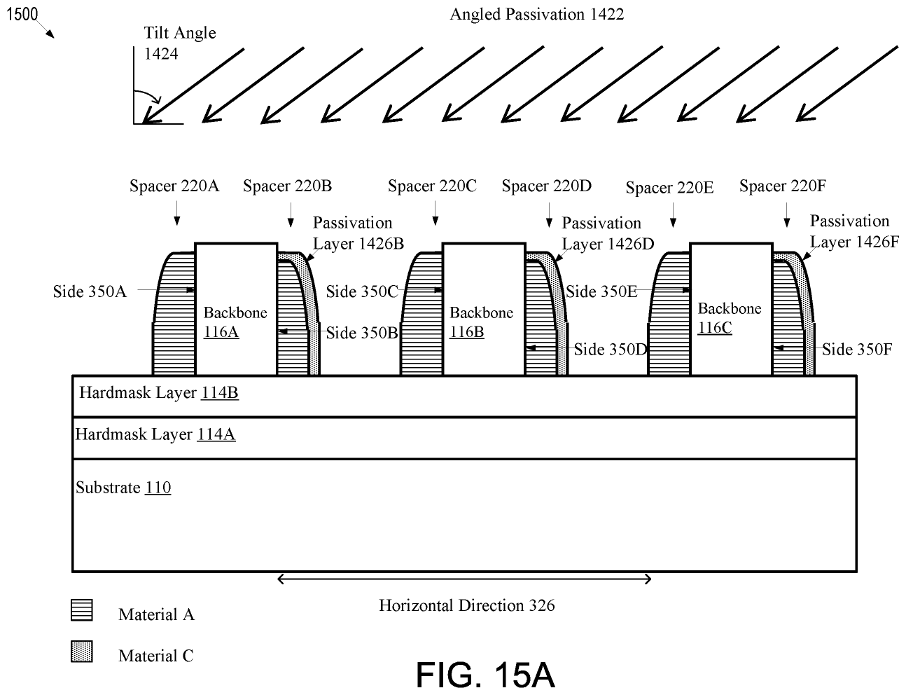

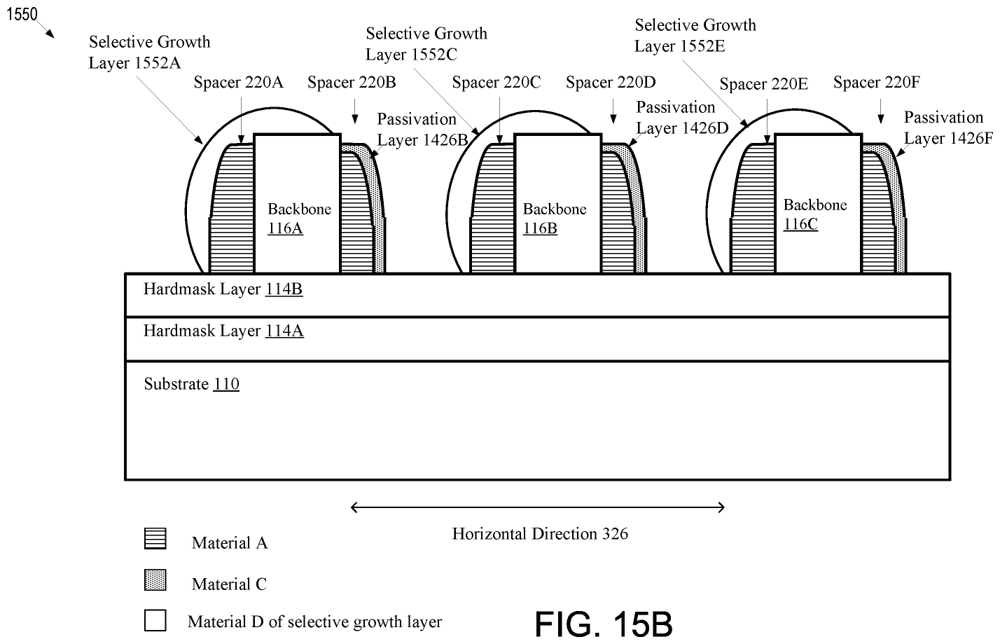

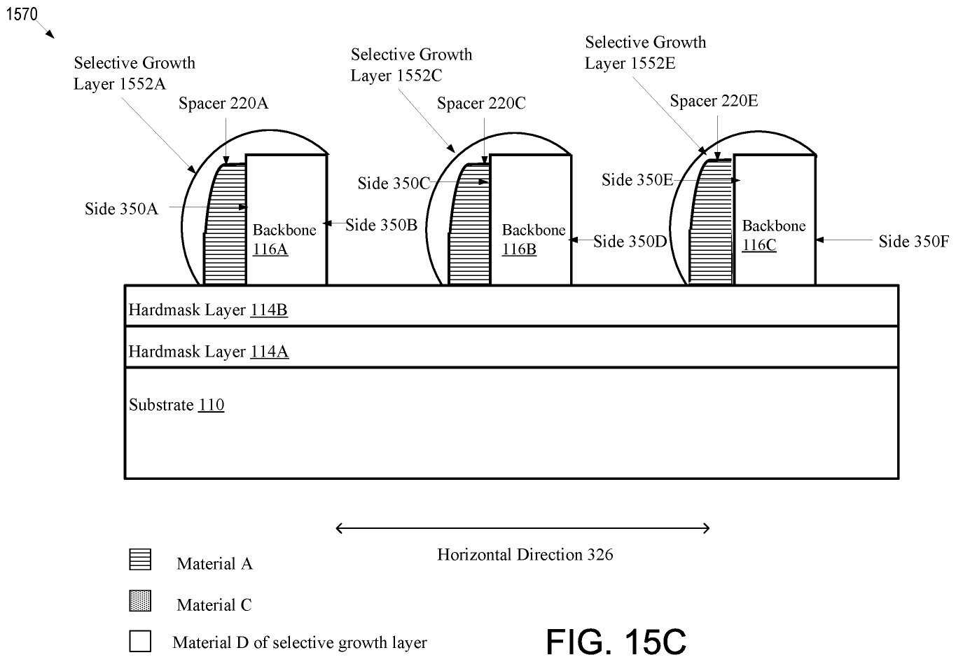

FIGS. 15A-C illustrate processes for the adjustment of etch properties associated with a first population of spacers and the removal of the first population or a second population of spacers selective the opposite population of spacers using selective angled passivation, selective growth, and etch, in accordance with implementations. FIG. 15A illustrates process 1500 of angled passivation 1422. Process 1500 may be similar to process 1400 with respect to FIG. 14A, as described above. Process 1500 shows angled passivation 1422 of the population of even spacers (e.g., spacers 220B, 220D, and 220F) selective to the population of odd spacers (e.g., spacers 220A, 220C, and 220E). A passivation layer (e.g., passivation layer 1426B, 1426D, and 1426F) may be formed in or on the respective spacers (e.g., spacers 220B, 220D, and 220F).

In FIG. 15B, process 1550 shows the selective growth of selective growth layers 1552 on odd spacers (e.g., spacers 220A, 220C, and 220E). In implementations, the passivation layer 1426 on the respective spacers (e.g., spacers 220B, 220D, and 220F) may prevent the surface of the passivation layer 1426 from being nucleating surfaces. In implementations, the passivation layer 1426 formed by the plasma may render the surface of the respective spacers, such as the even spacers, hydrophobic, and block the deposition of another material, such as selective growth layer 1552. Selective growth of a material, such as material D, may be performed on surfaces that are not passivated, such as the odd spacers. In implementations, the selective growth of the selective growth layers (e.g., selective growth layer 1552A, 1552C, and 1552E) may change the etch properties associated with the underlying spacers (e.g., spacers 220A, 220C, and 220E), and protect the underlying material from being subsequently etched. It may be noted that the selective growth layer 1552 may not change the etch properties of the affected spacers themselves, but form a protective layer with different etch properties from the passivated layer 1426 or passivated spacers (e.g., spacers 220B, 220D, and 220F).

In implementations, the selective growth layers 1552 may be formed from self-assembled monolayers (SAMs) that are organic molecular assemblies formed on surfaces by absorption and are organized into ordered domains. In implementations, a chemically selective reaction may occur that allows the SAMs to react with the material of the body (e.g., the surface and the exposed odd spacers or backbone structures 116) but not react with passivation layer 1426 of the even spacers. In one implementation, the SAMs may be Silane-based SAMs. In implementations, SAMs that attach preferentially to dielectric surfaces may be assembled in a solution. In another implementation, the SAMs may be deposited using a spin coating process. In an implementation, the SAMs may be applied to the center of the substrate 110 and the substrate 110 may be spun to spread the SAMs by centrifugal force. In yet another implementation, the SAMs may be deposited using a vapor phase deposition process where SAMs in a vapor phase are condensed to form a thin film. Examples of SAMs may include molecules with small or long (C1-C22) Alkyl chains or fluorinated chains and head groups that may include Alkoxysilanes, Aminosilanes and Chlorosilanes. In another implementation, the SAMs may be Thiol-based SAMs and the dielectric material may be a metal or metal oxide. SAMs that attach preferentially to metals or metal oxides may be assembled in the solution, spin coating or vapor phase deposition using molecules with head groups such as Alkenes, Alkynes, Amines, Phosphines, Thiols, Phosphonic acids or Carboxylic acids that selectively combine with metals. In some implementations, the selective growth layer 1552 may react with both metals and dielectric material.

In FIG. 15C, process 1570 shows an etch of passivated spacers (e.g., spacers 220B, 220D, and 220F) selective to spacers covered by the selective growth layers 1552 (e.g., spacers 220A, 220C, and 220E). The etch properties of the selective growth layer 1552 may protect the underlying spacers (e.g., spacers 220A, 220C, and 220E) from being removed during the etching of the passivated spacers.

In still other implementations, the SAMs may form a passivation layer, rendering the surface of the selective growth layer 1552 hydrophobic, blocking the deposition of a subsequent material on the surface of the selective growth layer 1552. Other examples of chemical compounds that may be used as passivants include Octadecylphosphonic acid or Octadecylthiol. With reference to FIG. 15B, selective growth layers 1552 and passivation layers 1426 may both be passivated, in implementations. A subsequent layer (not shown) may be grown on the passivation layer 1426 via SAMs, selective to the passivated selective growth layer 1552, or vice versa. In a subsequent process, either the odd spacers or even spacers may be etched selective to the other spacers.

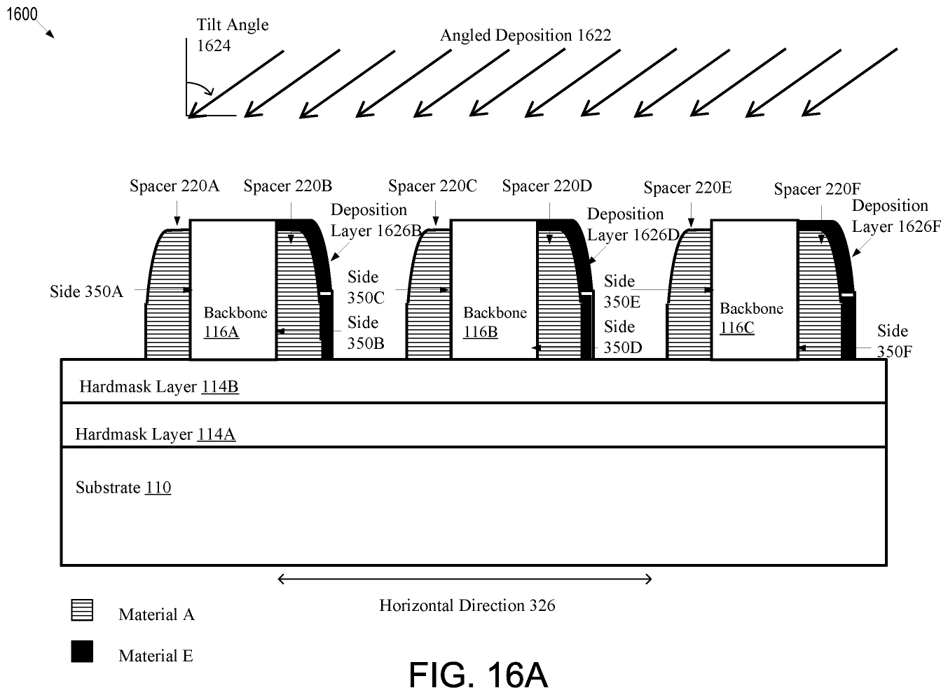

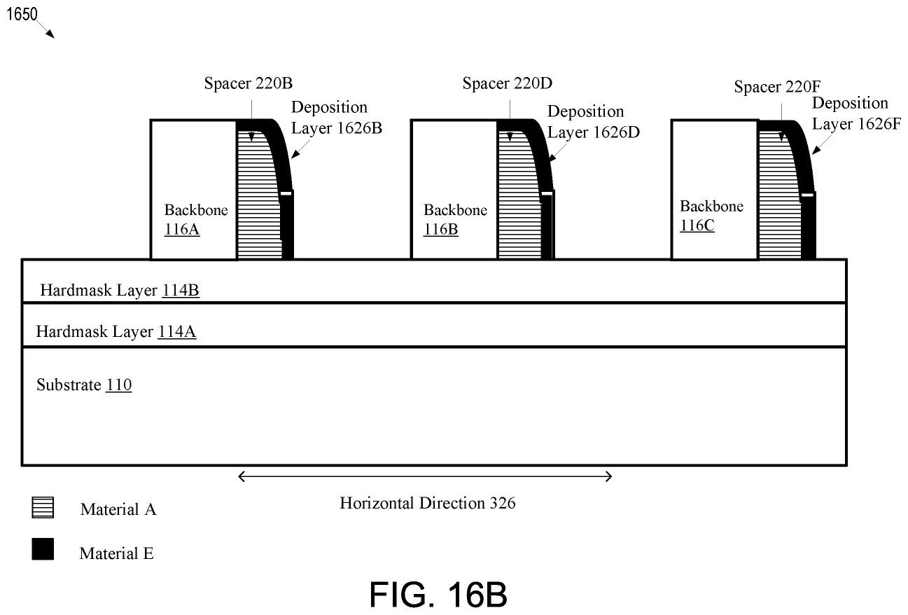

FIGS. 16A-B illustrate processes for the adjustment of etch properties associated with a first population of spacers and the removal of a second population of spacers selective the first population of spacers using selective angled deposition and etch, in accordance with implementations. In FIG. 16A, process 1600 shows angled deposition 1622 of deposition layer 1626 of the population of even spacers (e.g., spacers 220B, 220D, and 220F) selective to the population of odd spacers (e.g., spacers 220A, 220C, and 220E). A deposition layer (e.g., deposition layer 1626B, 1626D, and 1626F) may be formed on the respective spacers (e.g., spacers 220B, 220D, and 220F). Angled deposition 1622 may be performed at a tilt angle 1624 that uses elements, such as backbone structures 116, to shield one population of spacers (e.g., odd spacers) from the deposition material (e.g., material E) to prevent the deposition on one population of spacers and to enable the deposition of the deposition layer 1626 on another population of spacers (e.g., even spacers). In implementations, tilt angle 1624 may be in a range of 15 degrees to 40 degrees from vertical. It may be noted that the chosen tilt angle 1624 may be defined by the aspect ratio of desired features and may include parameters such as feature size, pitch, depth, etc. In one implementation, angled deposition 1622 may be performed using physical vapor deposition (PVD).

In implementations, the angled deposition 1622 of the deposition layers 1626 may change the etch properties associated with the underlying spacers (e.g., spacers 220A, 220C, and 220E), and protect the underlying material from being subsequently etched. It may be noted that in implementations, the deposition layers 1626 may not change the etch properties of the affected spacers themselves, but form a protective layer on the associated spacer where the protective layer has different etch properties than the adjacent odd spacer, for example.

In implementations, the deposition layers 1626 may include material such as Titanium, Tantalum, Copper, Rubidium, Cobalt, Nickle, Iron, Silicon, Germanium, Aluminum or nitrides or oxides of the materials. For example, any materials that may be deposited by physical vapor deposition (PVD) may be used as deposition layers 1626. In some implementations, oxides of deposition material may be deposited by reactive sputtering. In implementations, the thickness of the deposition layers 1626 may be determined by the etch selectivity of the odd spacers and the deposition layer 1626.

It may be noted that in some implementations some processes may be implemented while others are not implemented. For example in some implementations, subsequent to changing the etch properties associated with a population of spacers (e.g., even spacers) using angled deposition 1622, etch described with respect to FIG. 16B and spacer formation described with respect to FIGS. 4 and 5 may not be performed. In some implementations, changing the etch properties of a population of spacers (e.g., even spacers) using angled deposition 1622 may be followed by the removal of backbone structures 116 as described with respect to FIG. 6.

In FIG. 16B, process 1650 shows the selective removal of the odd spacers (e.g., spacers 220A, 220C, and 220E) selective to the even spacers (e.g., spacers 220B, 220D, and 220F) having a deposition layer 1626 above. The deposition layer 1626 may have different etch properties than the odd spacers. The odd spacers may be etched selective to the even spacers having a deposition layer 1626 above based on the difference in etch properties.

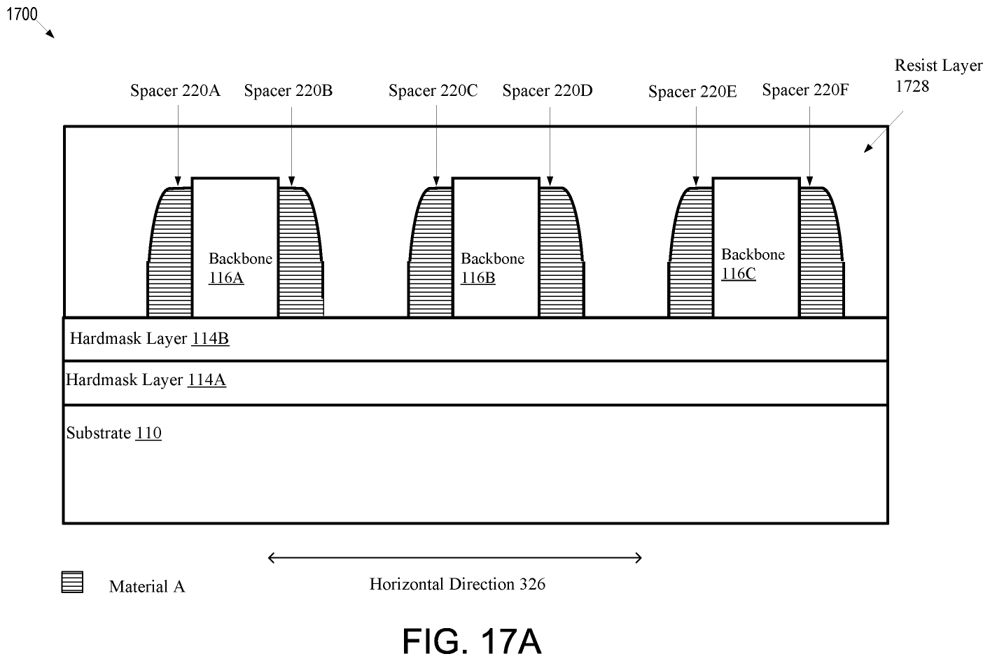

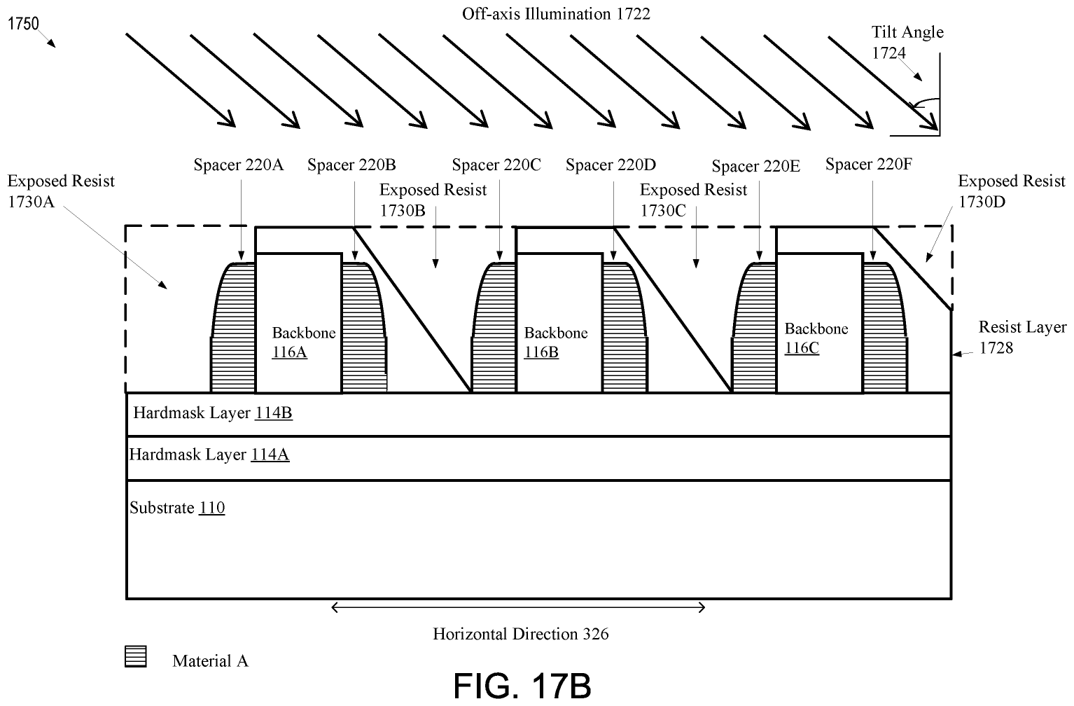

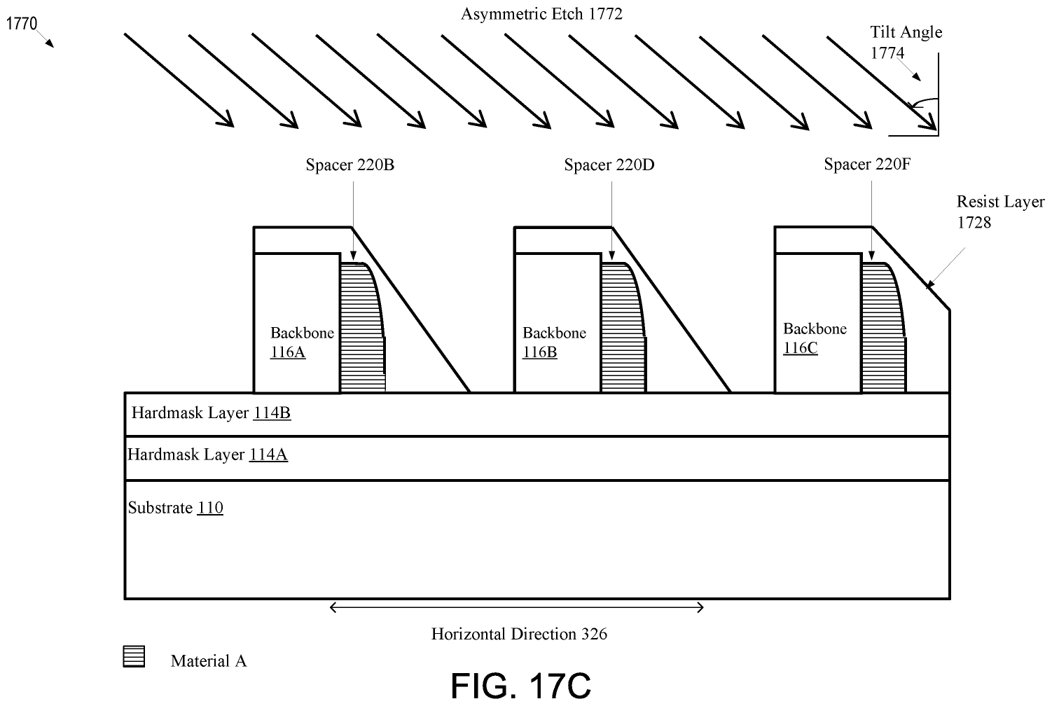

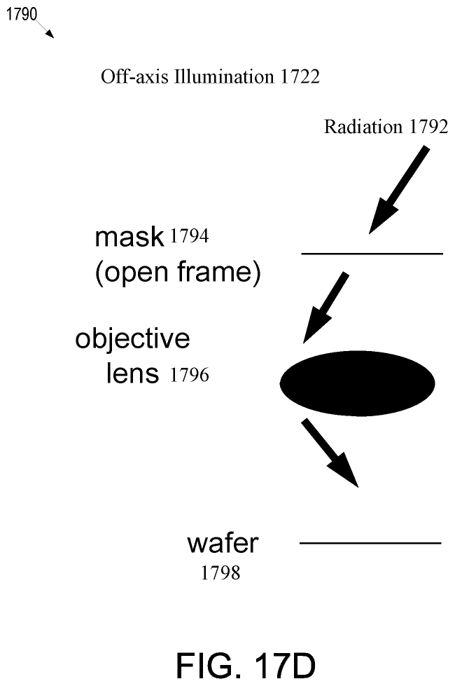

FIGS. 17A-C illustrate processes for the adjustment of etch properties associated with first population of spacers and the removal of a second population of spacers selective the first population of spacers using a resist layer, off-axis illumination, and resist removal, in accordance with implementations. In FIG. 17A, process 1700 shows the deposition of resist layer 1728. A resist layer may be a layer that may be patterned to transfer the pattern to the below materials on which the resist layer is deposited above. In implementations, the resist layer 1728 may be positive or negative resist. For purposes of illustration, rather than limitation, resist layer 1728 is shown as positive resist, unless otherwise described.

In FIG. 17B, process 1750 shows off-axis illumination 1722 using a form of radiation. The off-axis illumination 1722 may be at tilt angle 1724. In implementations, the choice of wavelength of the radiation, tilt angle 1724 from vertical, or polarization (among other parameters) may depend on the aspect ratio and other stack details. As illustrated, off-axis illumination 1722 exposes some areas of the resist (e.g. exposed resist 1730A, 1730B, 1730C, and 1730D) to the radiation, while other areas of the resist layer 1728 are not exposed. Off-axis illumination 1722 allows radiation to radiate at a specified tilt angle 1724 to create a shadowing effect. The shadowing effect may prevent radiation from being exposed to a population of spacers (e.g., even spacers) using an element, such as backbone structures 116, to block the radiation from the even spacers.

In FIG. 17C, process 1770 shows the selective removal of the odd spacer selective to the even spacers. In implementations, one or more processes may be used to remove the exposed resist 1730 and remove the odd spacers. In implementations, the remaining resist layer 1728 over the even spacers has different etch properties than the spacer material, and protects the underlying even spacer from being removed during the removal of the odd spacers.

In FIG. 17D, process 1790 shows off-axis illumination 1722, in accordance with some implementations. A source of radiation 1792 is exposed to the resist layer 1728 at an angle. In one implementation, radiation 1792 is flood exposed where mask 1794 is open. The radiation 1792 arrives at a lens 1796 at an angle and is directed towards the wafer 1798 at a complementary angle (e.g., tilt angle from vertical).

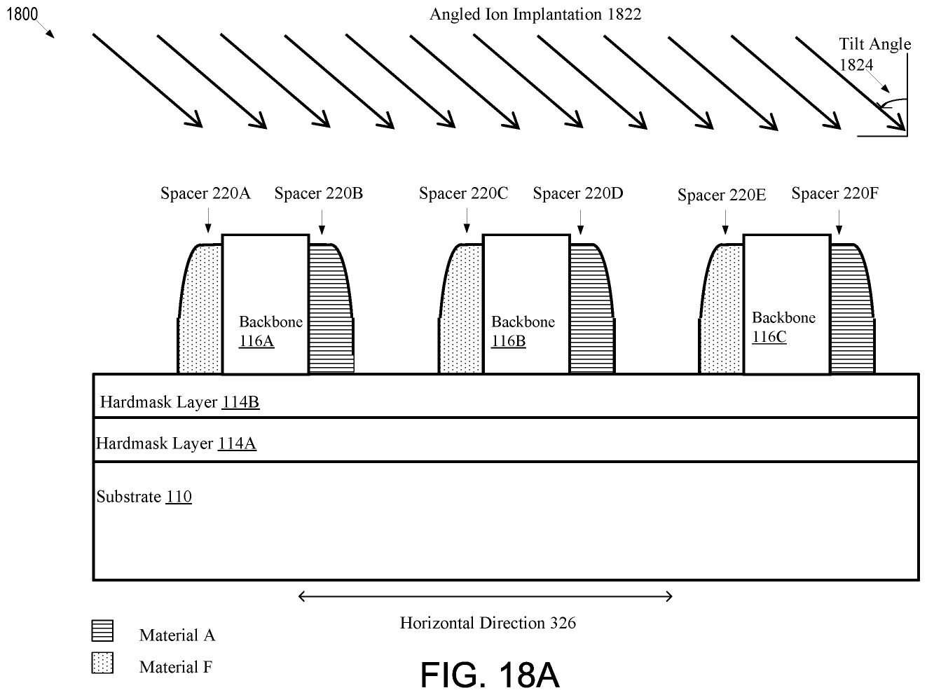

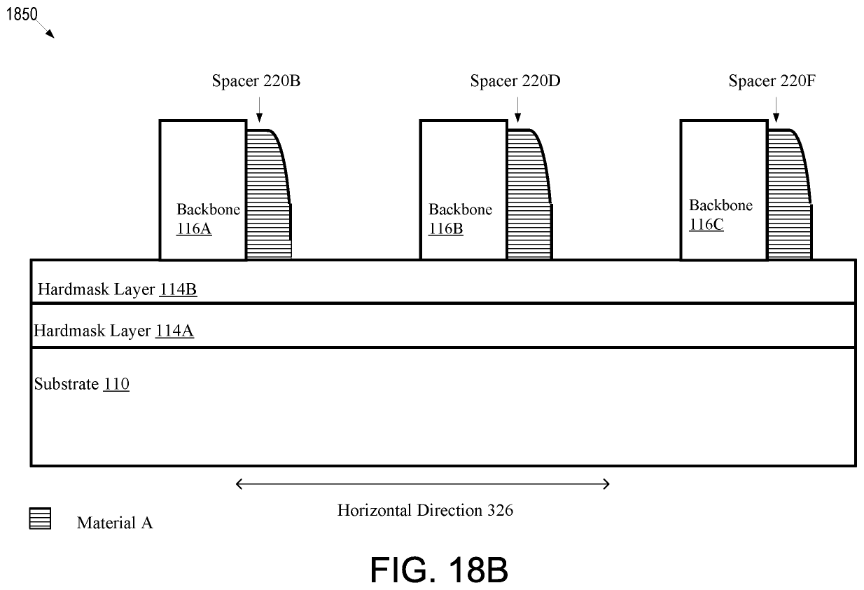

FIGS. 18A-B illustrate processes for the adjustment of etch properties associated with a first population of spacers and the removal of the first population or a second population of spacers selective the opposite population of spacers using selective angled ion implantation and etch, in accordance with implementations. In FIG. 18A, process 1800 shows angled ion implantation 1822 of ions into the population of odd spacers (e.g., spacers 220A, 220C, and 220E) selective to the population of even spacers (e.g., spacers 220B, 220D, and 220F). Angled ion implantation 1822 may be performed at a tilt angle 1824 that uses elements, such as backbone structures 116, to shield one population of spacers (e.g., even spacers) from the ion material (e.g., material F) and to prevent the implantation on one population of spacers while enabling the implantation of ions into another population of spacers (e.g., odd spacers). In implementations, tilt angle 1824 may be in a range of 15 degrees to 40 degrees from vertical. It may be noted that the chosen tilt angle 1824 may be defined by the aspect ratio of desired features and may include parameters such as feature size, pitch, depth, etc. Angled ion implantation 1822 may deposit a material throughout the selected spacers (e.g., area around surface and bulk), and change etch properties if the affected spacers. For example, after angled ion implantation 1822 of the odd spacers, the odd spacer may have a different etch property than even spacers. In implementations, the difference in etch properties may allow of the removal of either the odd spacers or the even spacers selective to the other population of spacers.

In implementations, angled ion implantation 1822 may change the material properties (such as etch properties) of the bulk of spacers 220A, 220C, and 220E. In implementations, angled ion implantation 1822 may increase the etch rate or decrease the etch rate for the affected spacers.

For example, the spacer material A may be SiO2. Argon ions may be implanted into the odd spacers using angled ion implantation 1822. The Argon doped spacers may be removed selective to the undoped SiO2 spacers. In another example, spacer material A may be amorphous Silicon (a-Si). A combination of one or more of Nitrogen gas (N2), Oxygen gas (O2), Carbon, or Methane (CH4) may be used in a high temperature annealing process to form a silicide, nitride, or oxide. The annealing process may be performed on odd spacers or even spacers. In other implementations, the annealing process may be subsequently performed on the spacers on the opposite side of backbone structures 116 to form spacers of an alternate material. Either the odd spacers or even spacers may be removed selective to the other population of spacers. In another example, spacer material A may be Carbon. Silicon ions may be implanted into the odd spacers using angled ion implantation 1822.

It may be noted that in some implementations some processes may be implemented while others are not implemented. For example in some implementations, subsequent to changing the etch properties of a population of spacers (e.g., odd spacers) using angled ion implantation 1822, etch described with respect to FIG. 18B and spacer formation described with respect to FIGS. 4 and 5 may not be performed. In some implementations, changing the etch properties of a population of spacers (e.g., odd spacers) using angled ion implantation 1822 may be followed by the removal of backbone structures 116 as described with respect to FIG. 6.

In FIG. 18B, process 1850 shows the removal of the odd spacers (e.g., spacers 220A, 220C, and 220E) selective to the population of even (e.g., spacers 220B, 220D, and 220F), using a selective etch or other process. As noted above, the odd spacers are shown as removed selective to the even spacers for purpose illustration, rather than limitation. In other implementations, the even spacers may be removed selective the odd spacers.

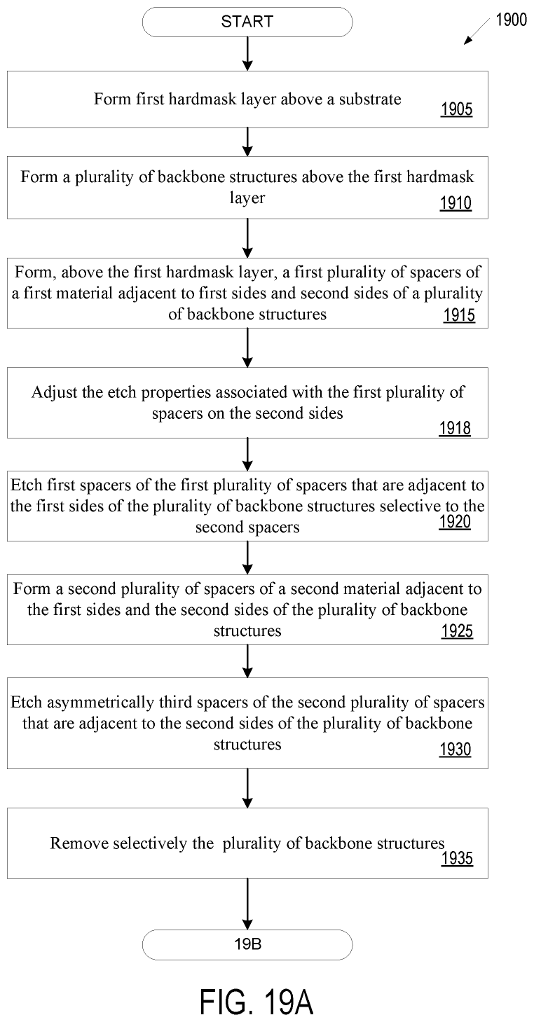

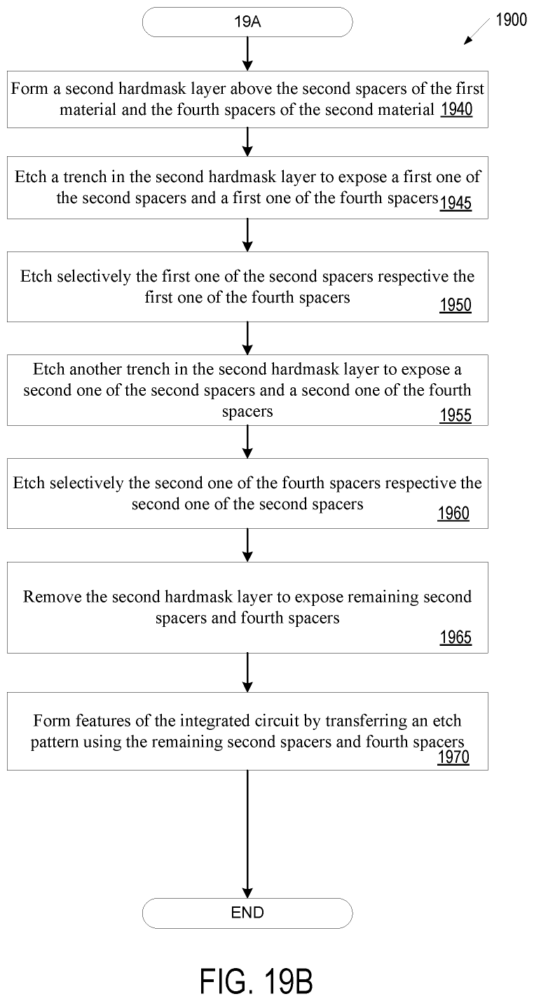

FIGS. 19A-B illustrate a flow diagram of a fabrication process for forming features of an integrated circuit, according to an implementation. It may be noted that elements of FIGS. 1-18B may be described below to help illustrate method 1900 and 1950. Method 1900 and 1950 may be performed as one or more operations. It may be noted that method 1900 and 1950 may be performed in any order and may include the same, more, or fewer operations. It may be noted that method 1900 and 1950 may be performed by one or more pieces of semiconductor fabrication equipment or fabrication tools.

Method 1900 begins at operation 1905 by forming a hardmask layer above a substrate. At operation 1910, multiple backbone structures 116 are formed above the first hardmask layer 114. At operation 1915, a first multitude of spacers 220 of a first material are formed adjacent to first sides and second sides of the multiple backbone structures 116.

At operation, 1918, the etch properties associated with the first multitude of spacers adjacent the second sides are adjusted. At operation 1920, first spacers (or second spacers) of the first multitude of spacers 220 that are adjacent to the first sides of the multiple backbone structures 116 are etched selective to spacers 220 that are adjacent to second sides of the multiple backbone structures 116. It may be noted that the spacers 220 may be prepared (e.g., etch properties adjusted) and selectively removed in a variety of ways as described with at least to respect to FIGS. 14-18B.

At operation 1925, a second multitude of spacers 430 of a second material adjacent to the first sides and the second sides of the multiple backbone structures 116 are formed. At operation 1930, third spacers of the second multitude of spacers 430 that are adjacent to the second sides (e.g., 350A, 350C, 350E) of the multiple backbone structures 116 are asymmetrically etched. The multiple backbone structures 116 protect fourth spacers of the second multitude of spacers 430 that are adjacent to the first sides of the multiple backbone structures 116 from being removed. At operation 1935, the multiple backbone structures 116 are selectively removed to leave the second spacers of the first material (e.g., spacers 220A, 220C, and 220E) and the fourth spacers of the second material (e.g., spacers 430B, 430D, and 430F).

Method 1900 continues from operation 1935 of method 1900, and begins at operation 1940 by forming a second hardmask layer 714A above the second spacers of the first material and the fourth spacers of the second material. At operation 1945, a trench 732 in the second hardmask layer 714A is etched to expose a first one of the second spacers (e.g., spacer 220A) and a first one of the fourth spacers (e.g., spacer 430D). At operation 1950, the first one of the second spacers (e.g., spacer 220A) is selectively etched respective the first one of the fourth spacers (e.g., spacer 430D). At operation 1955, another trench 932 in the second hardmask layer 914A is etched to expose a second one of the second spacers (e.g., spacer 220C) and a second one of the fourth spacers (e.g., spacer 430B). At operation 1960, the second one of the fourth spacers (e.g., spacer 430B) is selectively etched respective the second one of the second spacers (e.g., spacer 220C). At operation 1965, the second hardmask layer 914A is removed to expose remaining second spacers and fourth spacers (e.g., spacers 220A, 220C, 430C, and 430F). At operation 1970, features (e.g., features 1236 and 1238) of the integrated circuit are formed by transferring an etch pattern using the remaining second spacers and fourth spacers.

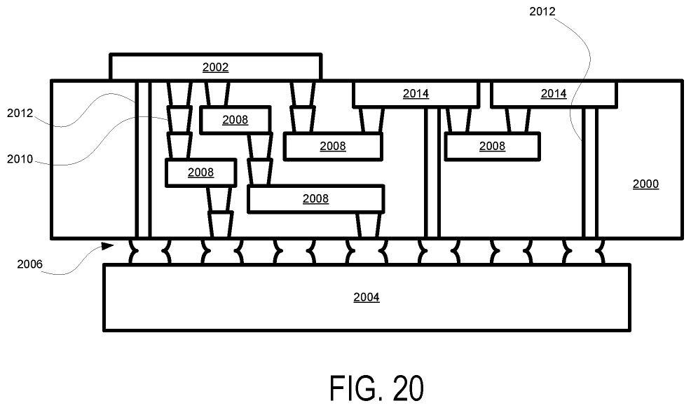

FIG. 20 illustrates an interposer, according to implementations. The interposer 2000 may be an intervening substrate used to bridge a first substrate 2002 to a second substrate 2004. The first substrate 2002 may be, for instance, an integrated circuit die, including integrated circuit die 1300. The second substrate 2004 may be, for instance, a memory module, a computer motherboard, backplane, or another integrated circuit die. In one implementation, first substrate 2002 may be an integrated circuit die described with respect to FIGS. 1-18B. Generally, the purpose of an interposer 2000 is to spread a connection to a wider pitch or to reroute a connection to a different connection. For example, an interposer 2000 may couple an integrated circuit die to a ball grid array (BGA) 2006 that can subsequently be coupled to the second substrate 2004. In some implementations, the first and second substrates 2002/2004 are attached to opposing sides of the interposer 2000. In other implementations, the first and second substrates 2002/2004 are attached to the same side of the interposer 2000. In further implementations, three or more substrates are interconnected by way of the interposer 2000.

The interposer 2000 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 2008 and vias 2010, including but not limited to through-silicon vias (TSVs) 2012. The interposer 2000 may further include embedded devices 2014, including both passive and active devices. Such devices include, but are not limited to, capacitors, decoupling capacitors, resistors, inductors, fuses, diodes, transformers, sensors, and electrostatic discharge (ESD) devices. More complex devices, such as radio frequency (RF) devices, power amplifiers, power management devices, antennas, arrays, sensors, or MEMS devices, may also be formed on the interposer 2000. In accordance with one or more implementations, apparatuses or processes disclosed herein may be used in the fabrication of interposer 2000.

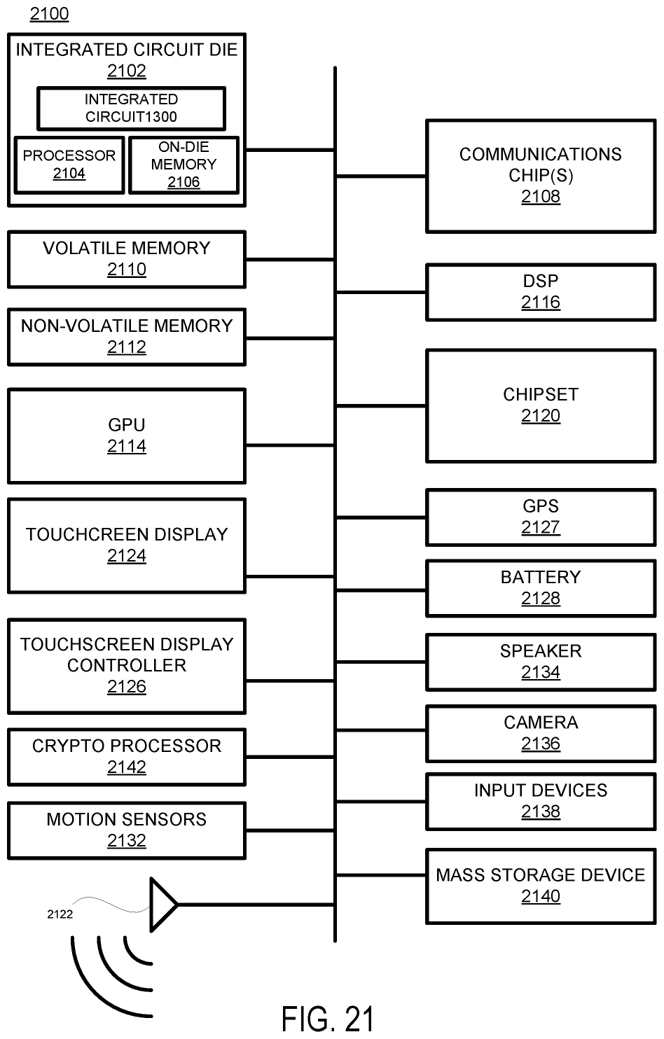

FIG. 21 is a computing device built in accordance with implementations of the present disclosure. The computing device 2100 may include a number of components. In one implementation, the components are attached to one or more motherboards. In an alternate implementation, some or all of these components are fabricated onto a single system-on-a-chip (SoC) die, such as an SoC used for mobile devices. In implementations, the components in the computing device 2100 include, but are not limited to, an integrated circuit 1300 and at least one communications logic unit 2108. In some implementations the communications logic unit 2108 is fabricated within the integrated circuit die 2102 while in other implementations the communications logic unit 2108 is fabricated in a separate integrated circuit chip that may be bonded to a substrate or motherboard that is shared with or electronically coupled to the integrated circuit die 2102. The integrated circuit die 2102 may include a CPU 2104 as well as on-die memory 2106, often used as cache memory that can be provided by technologies such as embedded DRAM (eDRAM), SRAM, or spin-transfer torque memory (STT-MRAM). It may be noted that in implementations integrated circuit die 2102 may include fewer elements (e.g., without processor 2104 and/or on-die memory 2106) or additional elements other than processor 2104 and on-die memory 2106. In one example, integrated circuit die 2102 may include an integrated circuit 1300 as described herein. In another example, integrated circuit die 2102 may include some or all the elements described herein, as well as include additional elements.

Computing device 2100 may include other components that may or may not be physically and electrically coupled to the motherboard or fabricated within an SoC die. These other components include, but are not limited to, volatile memory 2110 (e.g., DRAM), non-volatile memory 2112 (e.g., ROM or flash memory), a graphics processing unit 2114 (GPU), a digital signal processor 2116, a crypto processor 2142 (e.g., a specialized processor that executes cryptographic algorithms within hardware), a chipset 2120, at least one antenna 2122 (in some implementations two or more antenna may be used), a display or a touchscreen display 2124 (e.g., that may include integrated circuit die 2102), a touchscreen controller 2126, a battery 2128 or other power source, a power amplifier (not shown), a voltage regulator (not shown), a global positioning system (GPS) device 2127, a compass (not shown), a motion coprocessor or sensors 2132 (that may include an accelerometer, a gyroscope, and a compass), a microphone (not shown), a speaker 2134, a camera 2136, user input devices 2138 (such as a keyboard, mouse, stylus, and touchpad), and a mass storage device 2140 (such as hard disk drive, compact disk (CD), digital versatile disk (DVD), and so forth). The computing device 2100 may incorporate further transmission, telecommunication, or radio functionality not already described herein. In some implementations, the computing device 2100 includes a radio that is used to communicate over a distance by modulating and radiating electromagnetic waves in air or space. In further implementations, the computing device 2100 includes a transmitter and a receiver (or a transceiver) that is used to communicate over a distance by modulating and radiating electromagnetic waves in air or space.

The communications logic unit 2108 enables wireless communications for the transfer of data to and from the computing device 2100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some implementations they might not. The communications logic unit 2108 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, derivatives thereof, as well as any other wireless protocols that are designated as 3G, 4G, 5G, and beyond. The computing device 2100 may include a multitude of communications logic units 2108. For instance, a first communications logic unit 2108 may be dedicated to shorter range wireless communications such as Wi-Fi, NFC, and Bluetooth and a second communications logic unit 2108 may be dedicated to longer range wireless communications such as GPS, EDGE, GPRS, CDMA, WiMAX, LTE, Ev-DO, and others.

The processor 2104 (also referred to “processing device” herein) of the computing device 2100 includes one or more devices, such as transistors, RF filters, or LEDs, that are formed in accordance with implementations of the present disclosure. The term “processor” or “processing device” may refer to any device or portion of a device that processes electronic data from registers and/or memory to transform that electronic data into other electronic data that may be stored in registers and/or memory. Processor 2104 represents one or more general-purpose processing devices such as a microprocessor, a central processing unit, or the like. More particularly, the processor 2104 may be complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 2104 may also be one or more special-purpose processing devices such as an application specific integrated circuit (ASIC), a field programmable gate array (FPGA), a digital signal processor (DSP), network processor, or the like.

The communications logic unit 2108 may also include one or more devices, such as transistors, RF filters, or LEDs, that are formed in accordance with implementations of the present disclosure.

In further implementations, another component housed within the computing device 2100 may contain one or more devices, such as transistors, RF filters, or LEDs, that are formed in accordance with implementations of the present disclosure.

In various implementations, the computing device 2100 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 2100 may be any other electronic device that processes data.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

Various operations are described as multiple discrete operations, in turn, in a manner that is most helpful in understanding the present disclosure, however, the order of description should not be construed to imply that these operations are necessarily order dependent. In particular, these operations need not be performed in the order of presentation.

The terms “over,” “above” “under,” “between,” “adjacent,” and “on” as used herein refer to a relative position of one material layer or component with respect to other layers or components. For example, one layer disposed above or over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

Implementations of the disclosure may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to Germanium, Indium Antimonide, Lead Telluride, Indium Arsenide, Indium Phosphide, Gallium Arsenide, Indium Gallium Arsenide, Gallium Antimonide, or other combinations of group III-V or group IV materials. Although a few examples of materials from which the substrate may be formed are described here, any material that may serve as a foundation upon which a semiconductor device may be built falls within the spirit and scope of the present disclosure.

A multitude of transistors, such as metal-oxide-semiconductor field-effect transistors (MOSFET or simply MOS transistors), may be fabricated on the substrate. In various implementations of the disclosure, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the disclosure may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as Hafnium, Silicon, Oxygen, Titanium, Tantalum, Lanthanum, Aluminum, Zirconium, Barium, Strontium, Yttrium, Lead, Scandium, Niobium, and Zinc. Examples of high-k materials that may be used in the gate dielectric layer include, but are not limited to, Hafnium Oxide, Hafnium Silicon Oxide, Lanthanum Oxide, Lanthanum Aluminum Oxide, Zirconium Oxide, Zirconium Silicon Oxide, Tantalum Oxide, Titanium Oxide, Barium Strontium Titanium Oxide, Barium Titanium Oxide, Strontium Titanium Oxide, Yttrium Oxide, Aluminum Oxide, Lead Scandium Tantalum Oxide, and Lead Zinc Niobate. In some implementations, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer. Further metal layers may be included for other purposes, such as a barrier layer.

For a PMOS transistor, metals that may be used for the gate electrode include, but are not limited to, Ruthenium, Palladium, Platinum, Cobalt, Nickel, and conductive metal oxides, e.g., Ruthenium Oxide. A P-type metal layer will enable the formation of a PMOS gate electrode with a workfunction that is between about 4.9 eV and about 5.2 eV. For an NMOS transistor, metals that may be used for the gate electrode include, but are not limited to, Hafnium, Zirconium, Titanium, Tantalum, Aluminum, alloys of these metals, and carbides of these metals such as Hafnium Carbide, Zirconium Carbide, Titanium Carbide, Tantalum Carbide, and Aluminum Carbide. An N-type metal layer will enable the formation of an NMOS gate electrode with a workfunction that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may consist of a combination of U-shaped structures and planar, non-U-shaped structures. For example, the gate electrode may consist of one or more U-shaped metal layers formed atop one or more planar, non-U-shaped layers.

In some implementations of the disclosure, a pair of sidewall spacers may be formed on opposing sides of the gate stack that bracket the gate stack. The sidewall spacers may be formed from a material such as Silicon Nitride, Silicon Oxide, Silicon Carbide, Silicon Nitride doped with Carbon, and Silicon Oxynitride. Processes for forming sidewall spacers are well known in the art and generally include deposition and etching process operations. In an alternate implementation, a multitude of spacer pairs may be used, for instance, two pairs, three pairs, or four pairs of sidewall spacers may be formed on opposing sides of the gate stack.

In implementations, source and drain regions are formed within the substrate adjacent to the gate stack of each MOS transistor. The source and drain regions may be formed using either an implantation/diffusion process or an etching/deposition process. In the former process, dopants such as Boron, Aluminum, Antimony, Phosphorous, or Arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a Silicon alloy such as Silicon Germanium or Silicon Carbide. In some implementations, the epitaxially deposited silicon alloy may be doped in situ with dopants such as Boron, Arsenic, or Phosphorous. In further implementations, the source and drain regions may be formed using one or more alternate semiconductor materials such as germanium or a group III-V material or alloy. In further implementations, one or more layers of metal and/or metal alloys may be used to form the source and drain regions.

In other implementations, one or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, Silicon Dioxide (SiO₂), Carbon doped oxide (CDO), Silicon Nitride, organic polymers such as Perfluorocyclobutane or Polytetrafluoroethylene, Fluorosilicate glass (FSG), and organosilicates such as Silsesquioxane, Siloxane, or Organosilicate glass. The ILD layers may include pores or air gaps to further reduce their dielectric constant.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims may generally be construed to mean “one or more” unless specified otherwise or clear from context to be directed to a singular form. Moreover, use of the term “an implementation” or “one implementation” or “an implementation” or “one implementation” throughout is not intended to mean the same implementation or implementation unless described as such. The terms “first,” “second,” “third,” “fourth,” etc. as used herein are meant as labels to distinguish among different elements and may not necessarily have an ordinal meaning according to their numerical designation.

1. A computing device, comprising:
a memory;
an integrated circuit, operatively coupled to the memory, the integrated circuit comprising:
a first plurality of features above a substrate; and
a second plurality of features above the substrate, wherein the first plurality of features and the second plurality of features are same features disposed in a first direction, wherein the first plurality of features interleave with the second plurality of features, and wherein the first plurality of features have a first size and the second plurality of features have a second size.

2. The computing device of claim 1, wherein each of the first plurality of features are disposed between a different two of the second plurality of features.

3. The computing device of claim 1, wherein the first plurality of features and the second plurality of features are gates of transistors.

4. The computing device of claim 1, wherein the first plurality of features and the second plurality of features are fins of transistors.

5. The computing device of claim 1, wherein the first size and the second size are a width in the first direction.

6. The computing device of claim 1, wherein the first size is an average width of the first plurality of features, and the second size is an average width of the second plurality of features, and the first size is different from the second size.

7. The computing device of claim 1, wherein the first plurality of features and the second plurality of features are a local subset of features of the integrated circuit.

8. A method of fabricating an integrated circuit comprising:
forming a plurality of backbone structures above a substrate;
forming a first plurality of spacers of a first material adjacent to first sides and second sides of the plurality of backbone structures;
adjusting etch properties associated with the first plurality of spacers adjacent the second sides; and
etching first spacers of first plurality of spacers that are adjacent to the first sides of the plurality of backbone structures selective to second spacers of the first plurality of spacers that are adjacent to the second sides of the plurality of backbone structures based the adjusted etch properties associated with the second spacers of the first plurality of spacers.

9. The method of claim 8, further comprising:
forming a second plurality of spacers of a second material adjacent to the first sides and the second sides of the plurality of backbone structures; and
etching asymmetrically third spacers of the second plurality of spacers that adjacent to the second sides of the plurality of backbone structures, wherein the plurality of backbone structures protect fourth spacers of the second plurality of spacers that are adjacent to the first sides of the plurality of backbone structures from being removed.

10. The method of claim 9, wherein the first material of the first plurality of spacers is a different material than the second material of the second plurality of spacers.

11. The method of claim 9, further comprising:
removing the plurality of backbone structures selective to the second spacers of the first material and the fourth spacers of the second material.

12. The method of claim 11, further comprising:
forming a hardmask layer above the second spacers of the first material and the fourth spacers of the second material;
etching a trench in the hardmask layer to expose a first one of the second spacers and a first one of the fourth spacers; and
etching the first one of the second spacers selective to the first one of the fourth spacers.

13. The method of claim 12, further comprising:
etching another trench in the hardmask layer to expose a second one of the second spacers and a second one of the fourth spacers or the second plurality of spacers; and
etching the second one of the fourth spacers selective the second one of the fourth spacers.

14. The method of claim 13, further comprising:
removing the hardmask layer to expose remaining second spacers and remaining fourth spacers; and
forming features of the integrated circuit by transferring an etch pattern using the remaining second spacers and the remaining fourth spacers.

15. The method of claim 14, wherein the features of the integrated circuit comprise fins of transistors.

16. The method of claim 14, wherein the features of the integrated circuit comprise gates of transistors.

17. A method of fabricating an integrated circuit comprising:
forming a plurality of backbone structures above a substrate;
forming a first plurality of spacers of a first material adjacent to first sides and second sides of the plurality of backbone structures;
adjusting etch properties associated with the first plurality of spacers adjacent the second sides; and
etching selectively one of first spacers of the first plurality of spacers that are adjacent to the first sides of the plurality of backbone structures or second spacers of the first plurality of spacers that are adjacent to the second sides of the plurality of backbone structures based the adjusted etch properties associated with the second spacers of the first plurality of spacers adjacent the second sides of the plurality of backbone structures.

18. The method of claim 17, further comprising:
forming a second plurality of spacers of a second material adjacent to the first sides and the second sides of the plurality of backbone structures;
etching asymmetrically third spacers the second plurality of spacers that are disposed above a remaining one of the first spacers or the second spacers of the first plurality of spacers, wherein the plurality of backbone structures protect fourth spacers of the second plurality of spacers that are on an opposite side of the plurality of backbone structures from being removed;
removing the plurality of backbone structures selective to first remaining spacers, wherein the first remaining spacers comprise the fourth spacers of the second material and the remaining one of the first spacers or second spacers of the first material;
forming a hardmask layer above the first remaining spacers;
etching a trench in the hardmask layer to expose a first one of the first remaining spacers in a first material and a second one of the first remaining spacers in the second material;
etching the first one of the remaining spacers in the first material selective to the second one of the remaining spacers of the second material to form the second remaining spacers;
removing the hardmask layer to expose the second remaining spacers; and
forming features of the integrated circuit by transferring an etch pattern using the second remaining spacers.

19. The method of claim 17, wherein adjusting the etch properties associated with the first plurality of spacers adjacent the second sides comprises:
performing angled passivation of the second spacers of the first plurality of spacers that are adjacent to the second sides of the plurality of backbone structures selective to the first spacers of the first plurality of spacers that are adjacent to the first sides of the plurality of backbone structures.

20. The method of claim 19, wherein etching selectively one of the first spacers or the second spacers comprises:
etching the first spacers selective to the second spacers based on the passivated second spacers having different etch properties than the first spacers.

21. The method of claim 17, wherein adjusting the etch properties associated with the first plurality of spacers adjacent the second sides comprises:
performing angled passivation of the second spacers of the first plurality of spacers that are adjacent to the second sides of the plurality of backbone structures selective to the first spacers of the first plurality of spacers that are adjacent to the first sides of the plurality of backbone structures; and
growing a layer above the first spacers selective to the second spacers, wherein the passivated second spacers prevents growth of the layer above the second spacers, wherein the second spacers are etched selective to the first spacers based on the passivated second spacers having different etch properties than the layer above the first spacers.

22. The method of claim 17, wherein adjusting the etch properties associated with the first plurality of spacers adjacent the second sides comprises:
performing angled deposition of a layer above the second spacers that are adjacent to the second sides of the plurality of backbone structures selective to the first spacers that are adjacent to the first sides of the plurality of backbone structures, wherein the first spacers are etched selective to the second spacers based on the layer above the second spacers having different etch properties than the first spacers.

23. The method of claim 17, wherein adjusting the etch properties associated with the first plurality of spacers adjacent the second sides comprises:
depositing a resist layer above the first spacers and the second spacers; and
exposing the resist layer to off-axis illumination that exposes the resist layer in a first area adjacent the first spacers and prevents exposure of the resist layer in a second area adjacent the second spacers.

24. The method of claim 23, wherein etching selectively one of the first spacers or the second spacers comprises:
etching the first spacers selective to the second spacers, wherein the resist layer in the first area adjacent the first spacers is removed and the resist layer in the second area remains to prevent etch of the second spacers.

25. The method of claim 17, wherein adjusting the etch properties associated with the first plurality of spacers adjacent the second sides comprises:
performing ion implantation on the second spacers that are adjacent to the second sides of the plurality of backbone structures selective to the first spacers that are adjacent to the first sides of the plurality of backbone structures, wherein the ion implantation changes the etch properties of the second spacers, and wherein one of the first spacers or second spacers is selectively etched based on the changed etch properties of the second spacers.
